(19) United States
(12) Patent Application Publication
(10) Pub. No.: US 2026/0293142 A1
(43) Pub. Date: Sep. 24, 2026

(54) SEMICONDUCTOR MEMORY DEVICE AND METHOD FOR MANUFACTURING SEMICONDUCTOR MEMORY DEVICE

(71) Applicant: Kioxia Corporation, Tokyo (JP)

(72) Inventor: Yoshihiro AWASHIMA, Yokkaichi Mie (JP)

(21) Appl. No.: 19/335,356

(22) Filed: Sep. 22, 2025

(30) Foreign Application Priority Data
Mar. 19, 2025 (JP) 2025-045402

(51) Int. Cl. H10B 43/40; H10B 41/41

(52) U.S. Cl. CPC H10B 43/40; H10B 41/41

(57) ABSTRACT

A semiconductor memory device includes a substrate and a first transistor. The first transistor includes a first gate insulating film having at least a portion facing a region between a first diffusion region and a second diffusion region, and a first gate electrode positioned on the opposite side of the first gate insulating film from the substrate. The first gate electrode includes a first conductive layer, a first insulating layer, and a second conductive layer. The first insulating layer is provided on a surface of a portion of the first conductive layer. The second conductive layer includes, when viewed from a first direction which is a thickness direction of the substrate, a first portion overlapping the first insulating layer and a second portion disposed at a position not overlapping the first insulating layer and overlapping the first conductive layer, and is electrically connected to the first conductive layer.

### CROSS-REFERENCE TO RELATED APPLICATIONS

This application is based upon and claims the benefit of priority from Japanese Patent Application No. 2025-045402, filed Mar. 19, 2025, the entire contents of which are incorporated herein by reference.

### FIELD

Embodiments described herein relate generally to a semiconductor memory device and a method for manufacturing the semiconductor memory device.

### BACKGROUND

A semiconductor memory device having a transistor is known.

### BRIEF DESCRIPTION OF THE DRAWINGS

FIG. 1 is a block diagram showing a part of a semiconductor memory device according to a first embodiment.

FIG. 2 is a diagram showing an equivalent circuit of a part of a memory cell array according to the first embodiment.

FIG. 3 is a cross-sectional view showing a part of the semiconductor memory device according to the first embodiment.

FIG. 4 is an enlarged view of an area enclosed by line F4 in the structure shown in FIG. 3.

FIG. 5 is a cross-section of the structure taken along line F5-F5 in FIG. 4.

FIG. 6A is a cross-section of the structure taken along line F6A-F6A in FIG. 3.

FIG. 6B is a cross-section of the structure taken along line F6B-F6B in FIG. 6A.

FIG. 6C is a cross-section of the structure taken along line F6C-F6C in FIG. 6A.

FIG. 7 is a cross-section of the structure taken along line F7-F7 in FIG. 6A.

FIG. 8 is a cross-section of the structure taken along line F8-F8 in FIG. 6A.

FIG. 9 is an enlarged view of an area enclosed by line F9 in the configuration shown in FIG. 8.

FIGS. 10A-10F are each a cross-sectional view illustrating a method for manufacturing the semiconductor memory device according to the first embodiment.

FIG. 11 is a cross-section of the structure taken along line F11-F11 in FIG. 10C.

FIG. 12A is a cross-sectional view illustrating a case in which slimming is not performed in the first embodiment.

FIG. 12B is a cross-sectional view illustrating a case in which slimming is performed in the first embodiment.

FIG. 13 is a cross-sectional view showing a part of a semiconductor memory device according to a first modification of the first embodiment.

FIG. 14 is a cross-section of the structure taken along line F14-F14 in FIG. 13.

FIG. 15 is a cross-sectional view showing a part of a semiconductor memory device according to a second modification of the first embodiment.

FIG. 16 is a cross-section of the structure taken along line F16-F16 in FIG. 15.

FIG. 17 is a cross-sectional view showing a part of a semiconductor memory device according to a third modification of the first embodiment.

FIG. 18 is a cross-sectional view showing a part of the semiconductor memory device according to a fourth modification of the first embodiment.

FIG. 19 is a cross-sectional view showing a part of a semiconductor memory device according to a second embodiment.

FIG. 20 is a cross-section of the structure taken along line F20-F20 in FIG. 19.

FIGS. 21A-21H are each a cross-sectional view illustrating a method for manufacturing the semiconductor memory device according to the second embodiment.

FIG. 22 is a cross-sectional view showing a part of a semiconductor memory device according to a first modification of the second embodiment.

FIG. 23 is a cross-sectional view showing a part of a semiconductor memory device according to a second modification of the second embodiment.

### DETAILED DESCRIPTION

Embodiments provide a semiconductor memory device that enables miniaturization, and a method for manufacturing the semiconductor memory device.

In general, according to one embodiment, a semiconductor memory device includes a substrate and a first transistor. The first transistor includes a first diffusion region and a second diffusion region provided in the substrate, a first gate insulating film having at least a portion facing a region between the first diffusion region and the second diffusion region, and a first gate electrode positioned on the opposite side of the first gate insulating film from the substrate. The first gate electrode includes a first conductive layer, a first insulating layer, and a second conductive layer. The first insulating layer is provided on a surface of a portion of the first conductive layer. The second conductive layer includes, when viewed from a first direction which is a thickness direction of the substrate, a first portion overlapping the first insulating layer and a second portion disposed at a position not overlapping the first insulating layer and overlapping the first conductive layer, and is electrically connected to the first conductive layer.

Hereinafter, a semiconductor memory device and a method for manufacturing the semiconductor memory device according to some embodiments will be described with reference to the drawings. In the following description, configurations having the same or similar functions are denoted by the same reference numerals. Duplicate description of such configurations may be omitted. In the following description, the numbers or the letters at the end may be omitted when it is not necessary to distinguish the components from each other. In the drawings described below, the illustrations of configurations that are not related to the description may be omitted.

In the present application, the terms are defined as follows. "Parallel", "orthogonal", or "same" may encompass "substantially parallel", "substantially orthogonal", or "substantially the same", respectively. "Connection" is not limited to mechanical connections and may include electrical connections. That is, the "connection" is not limited to a plurality of elements being directly connected to each other, and may include a plurality of elements being connected to each other with another element interposed therebetween. In the present application, the two terms "layer" and "film" are used as convenient expressions to distinguish between two or more parts, and do not imply any differences in structure or material. For this reason, a part referred to as a "layer" in the following description may be understood interchangeably as a "film". In the following description, a part referred to as a "film" may be understood interchangeably as a "layer".

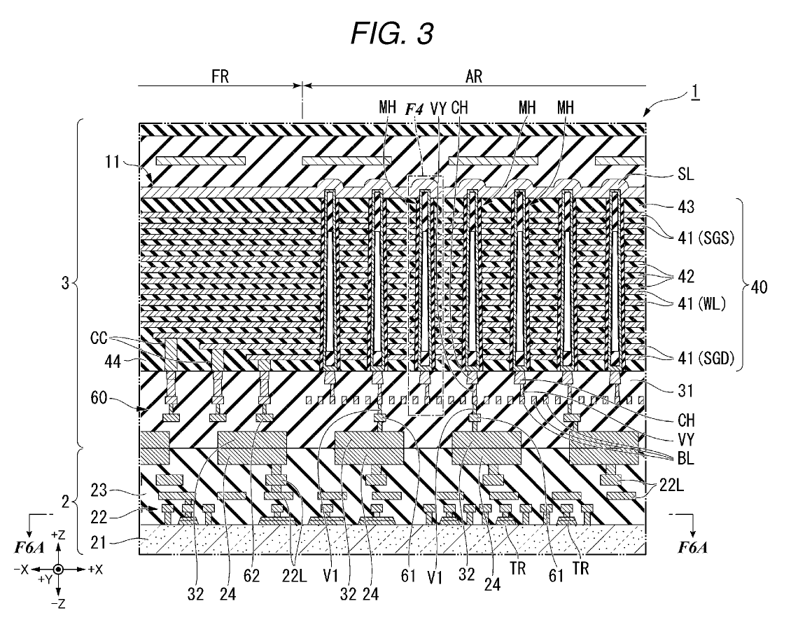

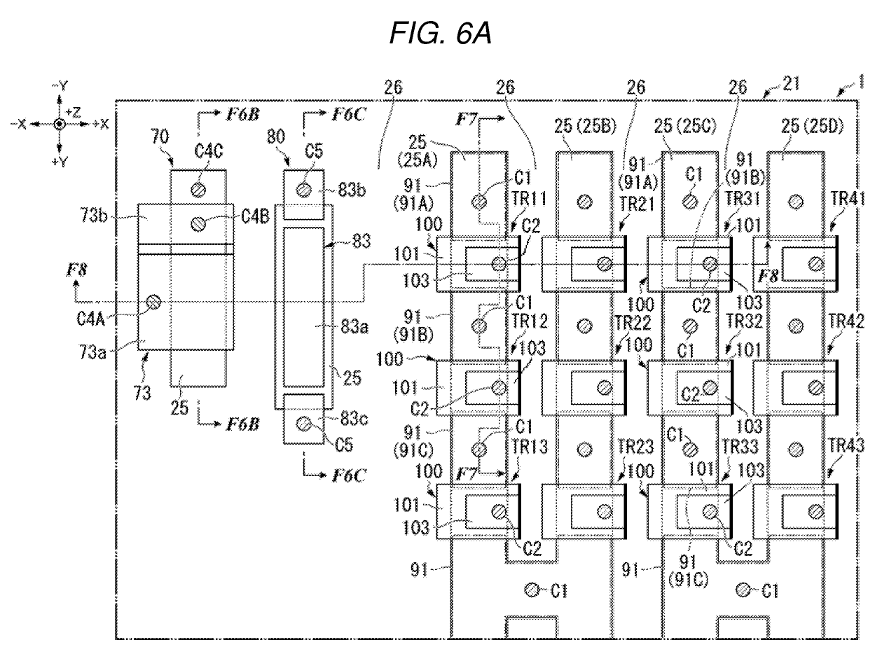

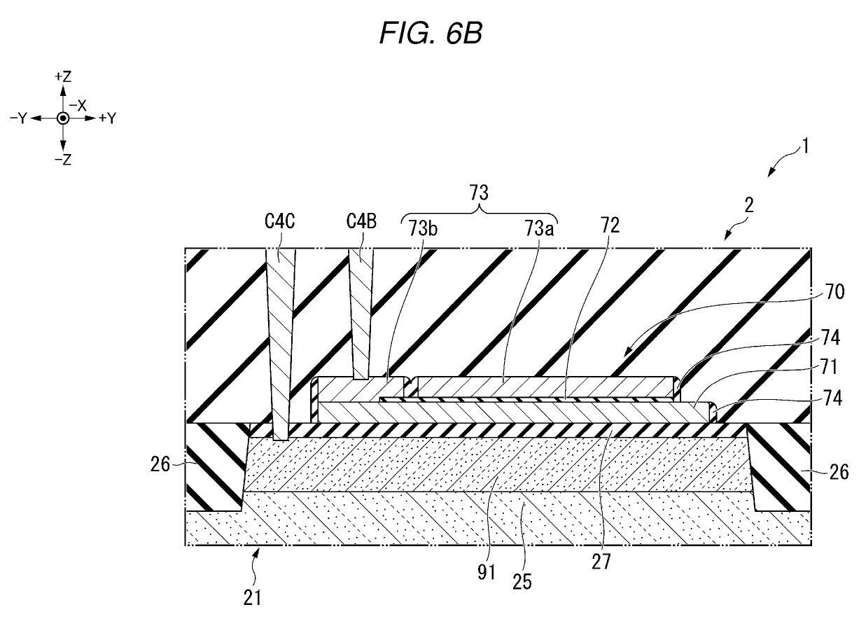

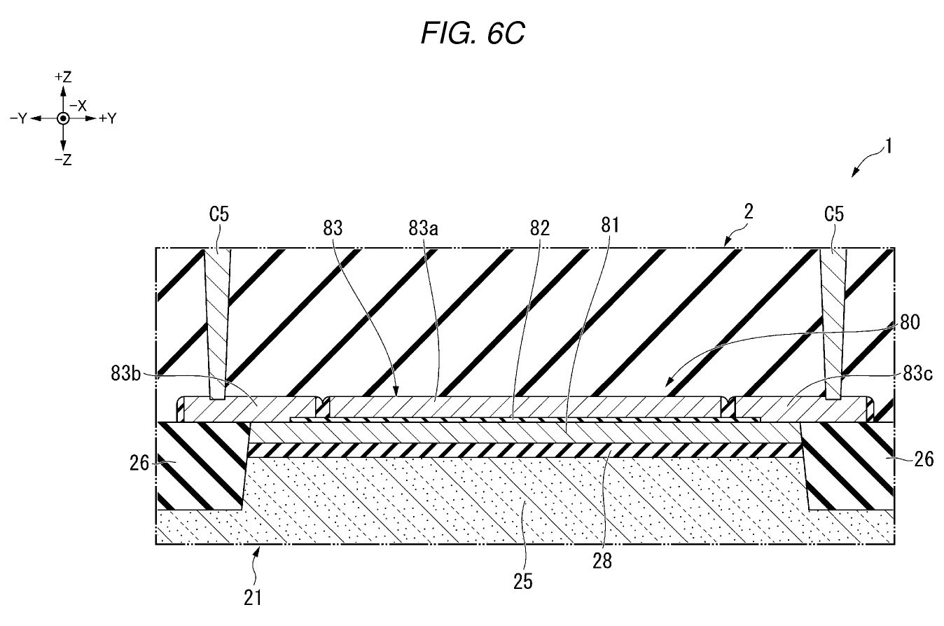

+X direction, -X direction, +Y direction, -Y direction, +Z direction, and -Z direction are defined as follows. The +X direction is a direction from one transistor TR11 toward another transistor TR21 to be described below (see FIG. 6A). The -X direction is the direction opposite to the +X direction. When the +X direction and the -X direction are not distinguished, they are simply referred to as the "X direction". The +Y direction is a direction intersecting (e.g., orthogonal to) the X direction. The +Y direction is a direction from one diffusion region 91A toward another diffusion region 91B in a semiconductor substrate 21 to be described below (see FIG. 6A). The -Y direction is the direction opposite to the +Y direction. When the +Y direction and the -Y direction are not distinguished, they are simply referred to as the "Y direction". The +Z direction is a direction intersecting (e.g., orthogonal to) the X direction and the Y direction. The +Z direction is a direction from a first chip 2 toward a second chip 3 to be described below (see FIG. 3). The -Z direction is the direction opposite to the +Z direction. When the +Z direction and the -Z direction are not distinguished, they are simply referred to as the "Z direction". The Z direction is a thickness direction of the semiconductor substrate 21. In the present application, the +Z direction side may be referred to as an "upper side" and the -Z direction side as a "lower side". In addition, in the present application, a position in the Z direction may be referred to as a "height". However, these expressions are for the convenience of description only and do not specify the direction of gravity.

### First Embodiment

### A1. Configuration of Semiconductor Memory device

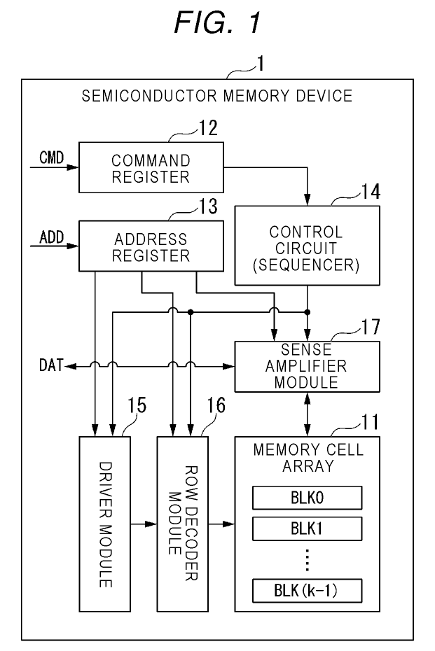

FIG. 1 is a block diagram showing a part of a semiconductor memory device 1 according to a first embodiment. The semiconductor memory device 1 is a nonvolatile semiconductor memory device and is a NAND flash memory, for example. However, the semiconductor memory device 1 is not limited to the NAND flash memory, and may also be a NOR-type memory, a magnetoresistive random access memory (MRAM), or a variable-resistance memory. Further, the semiconductor memory device 1 is not limited to the nonvolatile semiconductor memory device and may be a volatile semiconductor memory device such as a dynamic random access memory (DRAM).

The semiconductor memory device 1 can be connected to an external host device, and is used as a storage space for the host device. The semiconductor memory device 1 includes a memory cell array 11, a command register 12, an address register 13, a control circuit (sequencer) 14, a driver module 15, a row decoder module 16, and a sense amplifier module 17, for example.

The memory cell array 11 includes a plurality of blocks BLK0 to BLK(k-1) (k is an integer equal to or greater than 1). A Block BLK is a set of memory cell transistors. The block BLK is used as a data erasing unit. The memory cell array 11 includes a plurality of bit lines and a plurality of word lines. Each memory cell transistor is associated with one bit line and one word line.

The command register 12 stores a command CMD received by the semiconductor memory device 1 from the host device. The address register 13 stores address information ADD received by the semiconductor memory device 1 from the host device. The address information ADD is used to select the block BLK, the word line, and the bit line. The control circuit 14 controls various operations of the semiconductor memory device 1. For example, the control circuit 14 executes a write operation, a read operation, or an erasing operation, etc. of data based on the command CMD stored in the command register 12.

The driver module 15 includes a voltage generation circuit and generates a voltage for use in various operations of the semiconductor memory device 1. The row decoder module 16 transfers the voltage applied to a signal line corresponding to the selected word line to the selected word line. The sense amplifier module 17 applies a desired voltage to each bit line during the write operation. During the read operation, the sense amplifier module 17 determines the data stored in each memory cell transistor based on the voltage of the bit line or a current flowing through each bit line, and transfers the determination result to the host device as read data DAT.

### A2. Configuration of Memory Cell Array

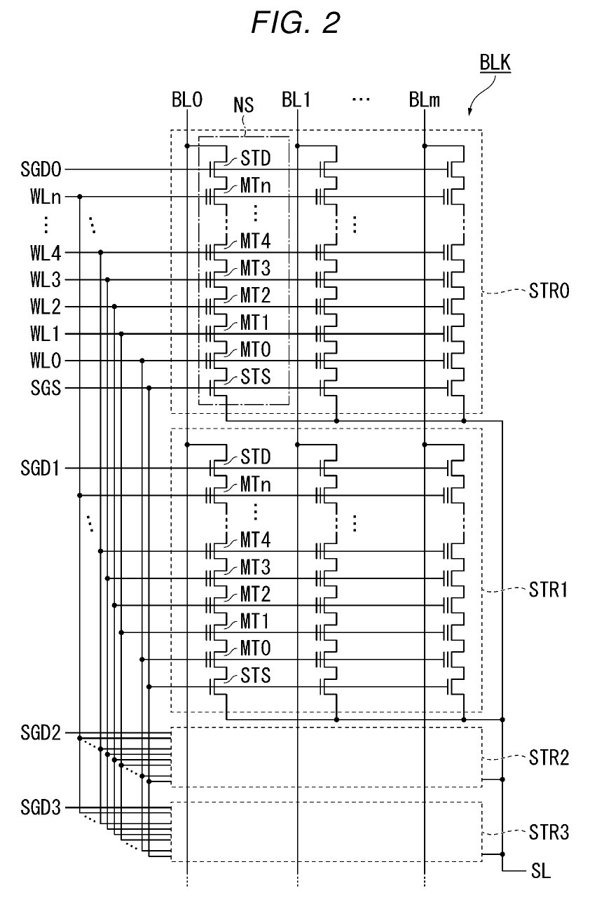

FIG. 2 is a diagram showing an equivalent circuit of a part of the memory cell array 11. FIG. 2 illustrates one block BLK in the memory cell array 11. The block BLK includes a plurality of string units STR (e.g., four string units STR0 to STR3).

Each string unit STR includes a plurality of NAND strings NS respectively associated with bit lines BL0 to BLm (m is an integer equal to or greater than 1). Each NAND string NS includes a plurality of memory cell transistors MT0 to MTn (n is an integer equal to or greater than 1), one or more drain-side select transistors STD, and one or more source-side select transistors STS.

In each NAND string NS, the memory cell transistors MT0 to MTn are connected in series. Each memory cell transistor MT includes a control gate and a charge storage portion. The control gate of the memory cell transistor MT is connected to one of word lines WL0 to WLn. Each memory cell transistor MT stores charges in the charge storage portion according to a voltage applied to the control gate via the word line WL, and stores the data in a nonvolatile manner.

The drain of the drain-side select transistor STD is connected to the bit line BL corresponding to the NAND string NS. The source of the drain-side select transistor STD is connected to one end of the memory cell transistors MT0 to MTn connected in series. The control gate of the drain-side select transistor STD is connected to one of drain-side select gate lines SGD0 to SGD3. The drain-side select transistor STD is electrically connected to the row decoder module 16 via the drain-side select gate line SGD. The drain-side select transistor STD connects the NAND string NS and the bit line BL when a predetermined voltage is applied to the corresponding drain-side select gate line SGD.

The drain of the source-side select transistor STS is connected to the other end of the memory cell transistors MT0 to MTn connected in series. The source of the source-side select transistor STS is connected to a source line SL. The control gate of the source-side select transistor STS is connected to the source-side select gate line SGS. The source-side select transistor STS connects the NAND string NS and the source line SL when a predetermined voltage is applied to the source-side select gate line SGS.

In the same block BLK, the control gates of the memory cell transistors MT0 to MTn are commonly connected to the corresponding word lines WL0 to WLn, respectively. In the same string unit STR, the control gate of the drain-side select transistor STD is commonly connected to the corresponding drain-side select gate line SGD. The control gate of the source-side select transistor STS is commonly connected to the source-side select gate line SGS. In the memory cell array 11, the bit lines BL are shared by the NAND strings NS that are assigned with the same column address in a plurality of string units STR.

### A3. Structure of Semiconductor Memory device

Next, a structure of the semiconductor memory device 1 will be described.

FIG. 3 is a cross-sectional view showing a part of the semiconductor memory device 1. The semiconductor memory device 1 includes, for example, the first chip 2 and the second chip 3. The second chip 3 is a chip bonded to the first chip 2.

### A3.1 First Chip

The first chip 2 is a circuit chip including a peripheral circuit. The first chip 2 includes, for example, the semiconductor substrate 21, a peripheral circuit 22, an insulating portion 23, and a plurality of pads 24.

The semiconductor substrate 21 is, for example, a substrate serving as a base for the first chip 2. At least a portion of the semiconductor substrate 21 is in a plate shape extending along the X direction and the Y direction. The semiconductor substrate 21 includes, for example, a semiconductor material such as silicon.

The peripheral circuit 22 is a circuit that allows the memory cell array 11 to function as described above. The peripheral circuit 22 includes a plurality of transistors TR and a plurality of wirings 22L to be described below. The peripheral circuit 22 includes one or more of the command register 12, the address register 13, the control circuit 14, the driver module 15, the row decoder module 16, and the sense amplifier module 17 described above. The insulating portion 23 covers the peripheral circuit 22. For example, the insulating portion 23 is formed by using tetraethyl orthosilicate (TEOS) (Si(OC₂H₅)₄). The plurality of pads 24 are provided on a surface of the insulating portion 23. Each of the pads 24 is electrically connected to the peripheral circuit 22.

### A3.2 Second Chip

The second chip 3 is an array chip including the memory cell array 11. For example, the second chip 3 includes the memory cell array 11, an insulating portion 31, and a plurality of pads 32. The insulating portion 31 and the plurality of pads 32 will be described first, and the memory cell array 11 will be described thereafter.

The insulating portion 31 covers the memory cell array 11 from the -Z direction side. The plurality of pads 32 are provided on a surface of the insulating portion 31. Each of the pads 32 is electrically connected to wiring (e.g., a wiring 61 or a wiring 62) provided in a wiring part 60 of the memory cell array 11 to be described below. In the present embodiment, the plurality of pads 24 of the first chip 2 and the plurality of pads 32 of the second chip 3 are bonded face to face, thereby integrating the first chip 2 and the second chip 3.

### A4. Memory Cell Array

Next, the memory cell array 11 will be described.

As shown in FIG. 3, the memory cell array 11 includes an array region AR and a hook-up region FR. The array region AR is a region where a plurality of memory pillars MH to be described below are provided and data can be stored. The hook-up region FR is a region in which a plurality of contacts CC to be described below are provided and a plurality of gate electrode layers 41 to be described below are connected to the wiring part 60.

The memory cell array 11 includes, for example, a stacked body 40, a source line SL, the plurality of memory pillars MH, a plurality of bit lines BL, a plurality of contacts CH for the memory pillars, a plurality of contacts VY for the memory pillars, a contact CC for the gate electrode layers, and the wiring part 60. The memory pillars MH will be described below.

### A4.1 Stacked Body

The stacked body 40 includes, for example, the plurality of gate electrode layers 41, a plurality of insulating layers 42, an insulating layer 43, and an insulating portion 44. The plurality of gate electrode layers 41 and the plurality of insulating layers 42 are alternately stacked one layer at a time in the Z direction.

The gate electrode layer 41 is a conductive layer extending in the X direction and the Y direction. Each gate electrode layer 41 includes a conductive material (e.g., tungsten, molybdenum, or silicon doped with impurities). Among the plurality of gate electrode layers 41, one or more (e.g., a plurality of) gate electrode layers 41 positioned on the upper side serve as the source-side select gate lines SGS. An intersection between the source-side select gate line SGS and a channel layer 52 (to be described below) of each memory pillar MH serves as the source-side select transistor STS described above. Among the plurality of gate electrode layers 41, one or more (e.g., a plurality of) gate electrode layers 41 positioned on the lower side serve as the drain-side select gate lines SGD. An intersection between the drain-side select gate line SGD and the channel layer 52 (to be described below) of each memory pillar MH serves as the drain-side select transistor STD described above. Among the plurality of gate electrode layers 41, at least some of the remaining gate electrode layers 41, which are provided between the gate electrode layers 41 serving as the source-side select gate lines SGS and the drain-side select gate lines SGD, serve as the word lines WL. In the present embodiment, the intersection of the word line WL and the channel layer 52 (described below) of each memory pillar MH serves as the memory cell transistor MT described above.

The plurality of gate electrode layers 41 have different lengths in the X direction in the hook-up region FR. For example, the length of the plurality of gate electrode layers 41 in the X direction increases as the gate electrode layer 41 is positioned closer to the +Z direction side. As a result, end portions of the plurality of gate electrode layers 41 are disposed in a stepped shape in the hook-up region FR.

The insulating layer 42 is an interlayer insulating film provided between two adjacent gate electrode layers 41 in the Z direction to insulate the two gate electrode layers 41 from each other. The insulating layer 42 includes, for example, a film containing silicon and oxygen (e.g., a silicon oxide film).

The insulating layer 43 is disposed between the uppermost gate electrode layer 41 and the source line SL. The insulating layer 43 includes, for example, a film containing silicon and oxygen (e.g., a silicon oxide film). The insulating portion 44 is an insulating portion provided in the hook-up region FR. For example, the insulating portion 44 is formed by using tetraethyl orthosilicate (TEOS) (Si(OC₂H₅)₄).

### A4.2 Source Line

The source line SL is provided on the insulating layer 43. The source line SL is, for example, a conductive layer or a semiconductor layer extending in the X direction and the Y direction. The source line SL includes, for example, a conductive material such as tungsten or molybdenum, or a semiconductor material including silicon.

### A4.3 Bit Line

The bit line BL is a wiring for selecting at least one memory pillar MH from among the plurality of memory pillars MH. The plurality of bit lines BL are disposed on the lower side (-Z direction side) with respect to the stacked body 40. The plurality of bit lines BL are arranged side by side in the X direction while being spaced apart from each other in the X direction. Each bit line BL extends in the Y direction. Each bit line BL extends so as to pass below the plurality of corresponding memory pillars MH.

Each bit line BL is connected to the channel layer 52 of the memory pillar MH to be described below via a contact VY and a contact CH. As a result, any memory cell transistor MT can be selected from among the plurality of memory cell transistors MT that are three-dimensionally arranged by the combination of the word line WL and the bit line BL.

### A4.4 Contact for Gate Electrode Layer

The contact CC is an electrical connection part that electrically connects the gate electrode layer 41 to the wiring 62 (to be described below) provided in the wiring part 60. The plurality of contacts CC are provided in, for example, the hook-up region FR of the memory cell array 11. The plurality of contacts CC extend in the Z direction within the stacked body 40 and are connected to different gate electrode layers 41. The contact CC has conductivity. The contact CC includes a conductive material (e.g., tungsten, molybdenum, or silicon doped with impurities).

### A4.5 Wiring Part

For example, the wiring part 60 is disposed between the stacked body 40 and the semiconductor substrate 21. The wiring part 60 includes, for example, a plurality of wirings 61, a plurality of vias V1, and a plurality of wirings 62.

The wiring 61 is an electrical connection part for electrically connecting the bit line BL and the pad 32. The plurality of wirings 61 are disposed under the plurality of bit lines BL, for example. Each wiring 61 extends, for example, in the X direction or the Y direction. The via V1 for electrically connecting the wiring 61 and the bit line BL is provided between the wiring 61 and the bit line BL.

The wiring 62 is an electrical connection part for electrically connecting the contact CC for the conductive layer and the pad 32. The wiring 62 is electrically connected to the gate electrode layer 41 via the contact CC for the conductive layer. A voltage is applied to the wiring 62 to select the gate electrode layer 41 (the word line WL, the drain-side select gate line SGD, or the source-side select gate line SGS).

### A5. Memory Pillar

Next, the memory pillar MH will be described.

The plurality of memory pillars MH are disposed in the X direction and the Y direction. Each memory pillar MH extends in the stacked body 40 in the Z direction and penetrates the stacked body 40. The memory pillar MH is an example of a "columnar body".

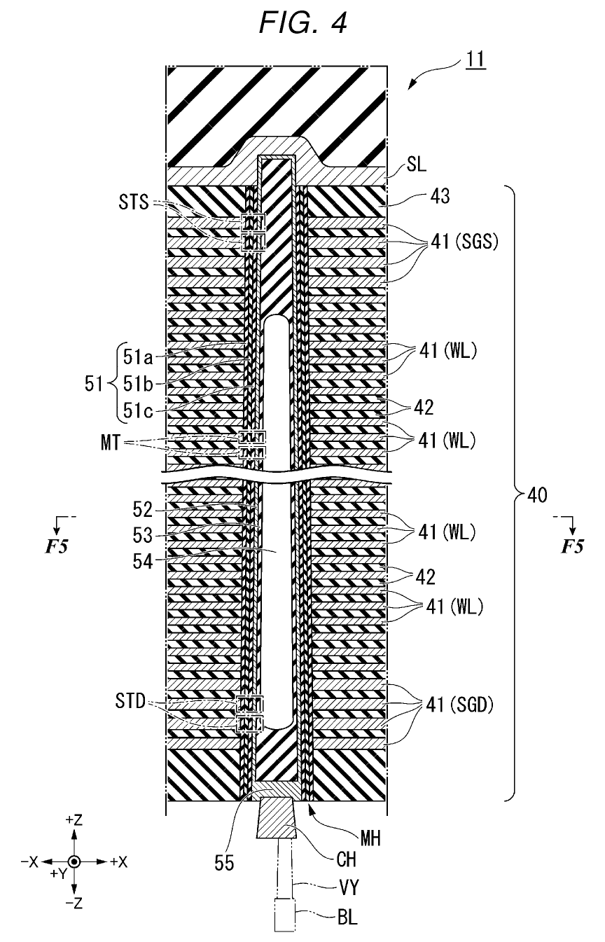

FIG. 4 is an enlarged cross-sectional view showing an area of the memory cell array 11 enclosed by line F4 in FIG. 3. For example, the memory pillar MH includes a memory film (multi-layer film) 51, the channel layer 52, an insulating portion 53, a cavity (air gap) 54, and a cap portion 55.

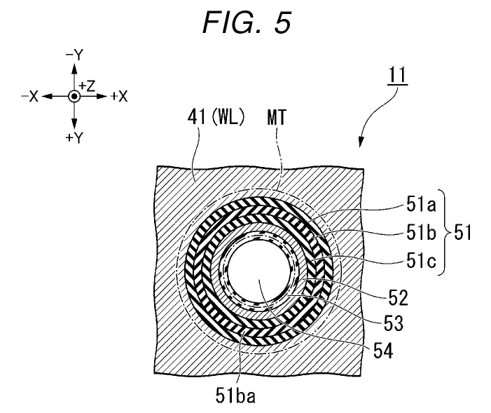

The memory film 51 is disposed on an outer periphery of the memory pillar MH. The memory film 51 extends in the Z direction. The memory film 51 is positioned between the plurality of gate electrode layers 41 and the channel layer 52. For example, the memory film 51 includes a block insulating film 51a, a charge trap film 51b, and a tunnel insulating film 51c in this order from an outer peripheral side of the memory film 51. The block insulating film 51a is an insulating film for preventing back tunneling. The charge trap film 51b is a functional film having a large number of crystal defects (trap levels) and capable of capturing charge in these crystal defects. A portion 51ba of the charge trap film 51b that is adjacent to each word line WL (see FIG. 5) is an example of the "charge storage portion" that can store information by storing electric charges. The tunnel insulating film 51c is a potential barrier between the charge trap film 51b and the channel layer 52.

The channel layer 52 is provided on an inner peripheral side of the memory film 51. The channel layer 52 is formed in an annular shape. The channel layer 52 includes a semiconductor material such as polysilicon. Impurities may be doped in the channel layer 52. The channel layer 52 forms a channel to electrically connect the bit line BL and the source line SL when a voltage is applied to the word line WL. The channel layer 52 is an example of a "semiconductor film".

FIG. 5 is a cross-section of the structure taken along line F5-F5 in FIG. 4. According to the configuration described above, at the same height as each word line WL, a Metal-Al-Nitride-Oxide-Silicon (MANOS) type memory cell transistor MT is formed by an edge of the word line WL adjacent to the memory pillar MH, the block insulating film 51a, the charge trap film 51b, the tunnel insulating film 51c, and the channel layer 52. The memory film 51 may include a floating gate type charge storage portion (floating gate electrode) in place of the charge trap film 51b as the charge storage portion. The floating gate type charge storage portion includes, for example, polysilicon including impurities.

Returning to FIG. 4, the remaining configuration of the memory pillar MH will be described.

The insulating portion 53 is provided on an inner peripheral side of the channel layer 52. The insulating portion 53 includes a film containing silicon and oxygen (e.g., a silicon oxide film). The insulating portion 53 extends over the entire length of the memory pillar MH in the Z direction except for a lower end of the memory pillar MH, for example. The cavity 54 is provided within a part of the insulating portion 53. However, the cavity 54 is optional and it is not necessary to provide it.

The cap portion 55 is provided below the insulating portion 53. The cap portion 55 is a semiconductor portion that includes a semiconductor material such as amorphous silicon or polysilicon. Impurities are doped in the cap portion 55, for example. The cap portion 55 is disposed on an inner peripheral side of a lower end of the memory film 51 and is integrally formed with the channel layer 52. The cap portion 55 forms a lower end of the memory pillar MH with a lower end of the channel layer 52. The contact CH is in contact with the cap portion 55 from the -Z direction side.

### A6. Structure of Peripheral Circuit

Next, the structure of the peripheral circuit 22 will be described.

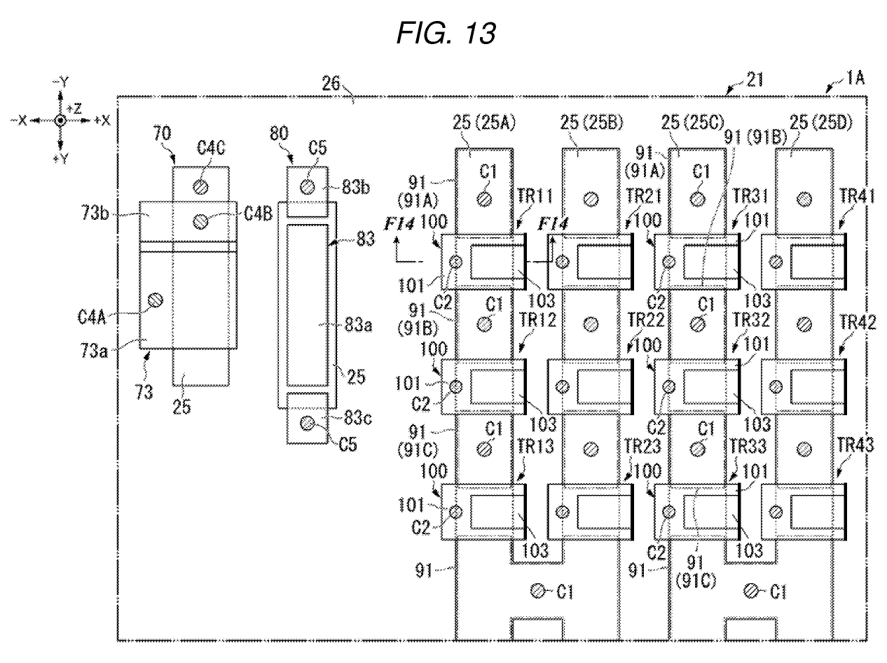

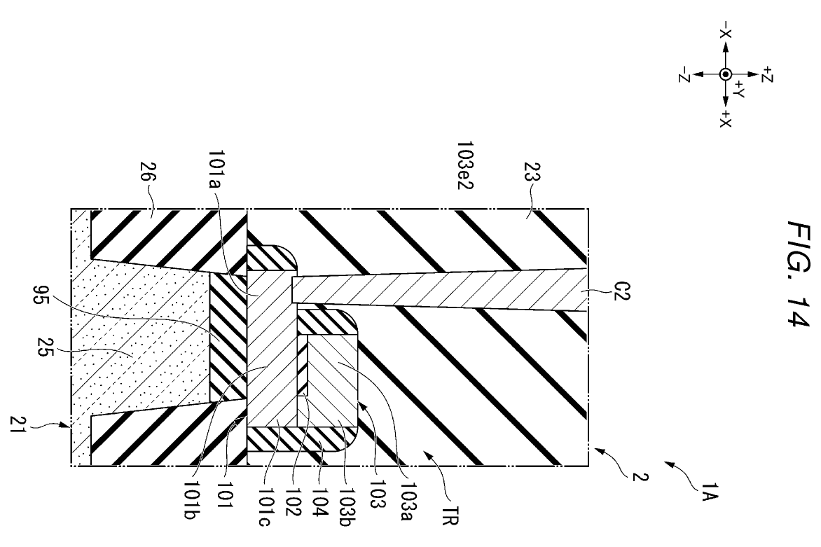

FIG. 6A is a cross-section of the structure taken along line F6A-F6A in FIG. 3. In FIG. 6A, illustrations of an insulating layer 102 and insulating films 74, 84, and 104 to be described below are omitted for convenience of description. The same applies to FIGS. 13, 15, 18, and 19 to be described below. In the present embodiment, the Z direction is an example of a "first direction". The X direction is an example of a "second direction". The Y direction is an example of a "third direction". In the present embodiment, the first chip 2 includes the semiconductor substrate 21, a plurality of capacitive elements 70 (only one is shown in FIG. 6A), a plurality of resistance elements 80 (only one is shown in FIG. 6A), and a plurality of transistors TR.

### A6.1 Semiconductor Substrate

First, the semiconductor substrate 21 is described. The semiconductor substrate 21 includes a plurality of element regions 25 and a plurality of element isolation portions 26. The element region 25 includes a semiconductor material such as silicon. The element region 25 is, for example, a P-type well region. Alternatively, the element region 25 may be an N-type well region.

The plurality of element regions 25 include, for example, element regions 25A to 25D. Each of the element regions 25A to 25D extends linearly in the Y direction. The element regions 25A to 25D are arranged with in the +X direction in the order of the element region 25A, the element region 25B, the element region 25C, and the element region 25D. The element isolation portion 26 is an insulating portion embedded in the semiconductor substrate 21. The element isolation portion 26 is provided around the plurality of element regions 25 and between two adjacent element regions 25 to electrically insulate the plurality of element regions 25. The semiconductor substrate 21 is an example of a "substrate".

### A6.2 Capacitive Element

Next, the capacitive element 70 will be described.

FIG. 6B is a cross-section of the structure taken along line F6B-F6B in FIG. 6A. The capacitive element 70 is an element capable of storing electric charges. The capacitive element 70 is provided on the element region 25. The capacitive element 70 includes, for example, an insulating film 27, a conductive layer 71, an insulating layer 72, a conductive layer 73, and an insulating film 74. Each of the conductive layer 71 and the conductive layer 73 includes a conductive material (e.g., silicon doped with impurities). Each of the insulating film 27 and the insulating layer 72 includes, for example, a film containing silicon and oxygen (e.g., a silicon oxide film). The insulating film 74 includes, for example, a film including silicon and nitrogen (e.g., a silicon nitride film). The insulating film 27, the conductive layer 71, the insulating layer 72, and the conductive layer 73 are stacked on the element region 25 in this order (i.e., in the order of the insulating film 27, the conductive layer 71, the insulating layer 72, and the conductive layer 73). The insulating film 74 is provided on side surfaces of the conductive layer 71, the insulating layer 72, and the conductive layer 73 in the X direction and the Y direction.

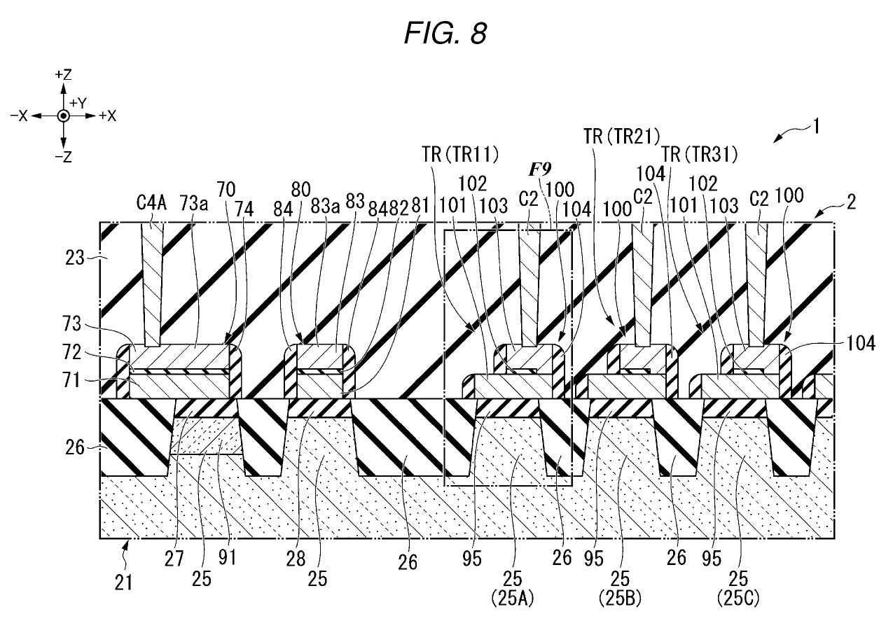

The conductive layer 73 includes a first portion 73a and a second portion 73b. The entirety of the first portion 73a of the conductive layer 73 overlaps the insulating layer 72 when viewed from the Z direction. The insulating layer 72 is disposed between the first portion 73a of the conductive layer 73 and the conductive layer 71, and electrically insulates the first portion 73a of the conductive layer 73 and the conductive layer 71. A contact C4A is connected to the first portion 73a of the conductive layer 73 from above (see FIGS. 6A and 8).

The second portion 73b of the conductive layer 73 is adjacent to the first portion 73a of the conductive layer 73 in the Y direction. The second portion 73b of the conductive layer 73 is disposed apart from the first portion 73a of the conductive layer 73. A portion of the insulating film 74 is provided between the second portion 73b of the conductive layer 73 and the first portion 73a of the conductive layer 73. The insulating film 74 electrically insulates the second portion 73b of the conductive layer 73 and the first portion 73a of the conductive layer 73. At least a part of the second portion 73b of the conductive layer 73 is provided outside the insulating layer 72, when viewed from the Z direction, and is connected to the conductive layer 71. The second portion 73b of the conductive layer 73 is electrically connected to the conductive layer 71. A contact C4B is connected to the second portion 73b of the conductive layer 73 from above.

In the present embodiment, the element region 25 overlapping the capacitive element 70 includes a diffusion region 91. The diffusion region 91 is formed by doping impurities on an upper portion of the semiconductor substrate 21. The diffusion region 91 has a lower electrical resistance than the region outside the diffusion region 91. A contact C4C is connected to the diffusion region 91 from above.

Each of the contacts C4A, C4B and C4C is provided between the capacitive element 70 and a wiring 22L (see FIG. 3), and electrically connects the capacitive element 70 and the wiring 22L. With this configuration, electric charges can be stored in a portion between the contact C4A and the contact C4B. Further, the electric charges can be stored in a portion between the contact C4B and the contact C4C. The structure of the capacitive element 70 is not limited to the examples described above. For example, the capacitive element 70 may store electric charges only in one of the portion between the contact C4A and the contact C4B and the portion between the contact C4B and the contact C4C.

### A6.3 Resistance Element

Next, the resistance element 80 is described.

FIG. 6C is a cross-section of the structure taken along line F6C-F6C in FIG. 6A. The resistance element 80 is an element having a predetermined electric resistance value. The resistance element 80 is provided on the element region 25. The resistance element 80 includes, for example, an insulating film 28, a conductive layer 81, an insulating layer 82, a conductive layer 83, and an insulating film 84 (see FIG. 8). Each of the conductive layer 81 and the conductive layer 83 includes a conductive material (e.g., silicon doped with impurities). Each of the insulating film 28 and the insulating layer 82 includes, for example, a film containing silicon and oxygen (e.g., a silicon oxide film). The insulating film 84 includes, for example, a film including silicon and nitrogen (e.g., a silicon nitride film). The insulating film 28, the conductive layer 81, the insulating layer 82, and the conductive layer 83 are stacked on the element region 25 in this order (i.e., in the order of the insulating film 28, the conductive layer 81, the insulating layer 82, and the conductive layer 83). The insulating film 84 is provided on side surfaces of the conductive layer 81, the insulating layer 82, and the conductive layer 83 in the X direction and the Y direction.

The conductive layer 83 includes a first portion 83a, a second portion 83b, and a third portion 83c. The entirety of the first portion 83a of the conductive layer 83 overlaps the insulating layer 82 when viewed from the Z direction. The insulating layer 82 is disposed between the first portion 83a of the conductive layer 83 and the conductive layer 81, and electrically insulates the first portion 83a of the conductive layer 83 and the conductive layer 81.

The second portion 83b of the conductive layer 83 is adjacent to the first portion 83a of the conductive layer 83 in the Y direction. The second portion 83b of the conductive layer 83 is disposed apart from the first portion 83a of the conductive layer 83. A portion of the insulating film 84 is provided between the second portion 83b of the conductive layer 83 and the first portion 83a of the conductive layer 83. The insulating film 84 electrically insulates the second portion 83b of the conductive layer 83 and the first portion 83a of the conductive layer 83. At least a part of the second portion 83b of the conductive layer 83 is provided outside the insulating layer 82, when viewed from the Z direction, and is connected to the conductive layer 81. The second portion 83b of the conductive layer 83 is electrically connected to the conductive layer 81. A contact C5 is connected to the second portion 83b of the conductive layer 83 from above.

The third portion 83c of the conductive layer 83 is adjacent to the first portion 83a of the conductive layer 83 in the Y direction. For example, the third portion 83c of the conductive layer 83 is disposed on the opposite side of the second portion 83b of the conductive layer 83 with respect to the first portion 83a of the conductive layer 83. The third portion 83c of the conductive layer 83 is disposed apart from the first portion 83a of the conductive layer 83. A portion of the insulating film 84 is provided between the third portion 83c of the conductive layer 83 and the first portion 83a of the conductive layer 83. The insulating film 84 electrically insulates the third portion 83c of the conductive layer 83 and the first portion 83a of the conductive layer 83. At least a part of the third portion 83c of the conductive layer 83 is provided outside the insulating layer 82, when viewed from the Z direction, and is connected to the conductive layer 81. The third portion 83c of the conductive layer 83 is electrically connected to the conductive layer 81. The contact C5 is connected to the third portion 83c of the conductive layer 83 from above.

The contact C5 is provided between the resistance element 80 and the wiring 22L (see FIG. 3), and electrically connects the resistance element 80 and the wiring 22L. With this configuration, a portion between the two contacts C5 may serve as a resistance element.

### A6.4 Transistor

For example, the transistor TR is provided as a part of the row decoder module 16 or a part of the sense amplifier module 17. For example, the transistor TR is provided in the row decoder module 16 and electrically connected to the word line WL. In this case, the transistor TR serves as a switch for selecting the word line WL. Instead, the transistor TR may be provided in the sense amplifier module 17 and electrically connected to the bit line BL. In this case, the transistor TR serves as a switch for selecting the bit line BL.

### A6.4.1 Transistor Arrangement Structure

As shown in FIG. 6A, a plurality of transistors TR are disposed in the X direction and the Y direction. The plurality of transistors TR includes, for example, transistors TR11 to TR13, TR21 to TR23, TR31 to TR33, and TR41 to TR43. The transistors TR11 to TR13 are provided on the element region 25A. The transistors TR21 to TR23 are provided on the element region 25B. The transistors TR31 to TR33 are provided on the element region 25C. The transistors TR41 to TR43 are provided on the element region 25D.

The transistors TR11 to TR13 are arranged in the +Y direction in the order of the transistors TR11, TR12 and TR13. The transistors TR21 to TR23 are arranged in the +Y direction in the order of the transistors TR21, TR22, and TR23. The transistors TR31 to TR33 are arranged in the +Y direction in the order of the transistors TR31, TR32, and TR33. The transistors TR41 to TR43 are arranged in the +Y direction in the order of the transistors TR41, TR42 and TR43.

With respect to the X direction, the transistors TR21 to TR23 are disposed on the +X direction side with respect to the transistors TR11 to TR13. The transistors TR31 to TR33 are disposed on the +X direction side with respect to the transistors TR21 to TR23. The transistors TR41 to TR43 are disposed on the +X direction side with respect to the transistors TR31 to TR33.

In the present embodiment, the transistors TR11, TR21, TR31, and TR41 are arranged in the X direction. The transistors TR12, TR22, TR32, and TR42 are arranged in the X direction. The transistors TR13, TR23, TR33, and TR43 are arranged in the X direction.

Each of the transistors TR11 to TR13, TR21 to TR23, TR31 to TR33, TR41 to TR43 described above has the same configuration, for example. Hereinafter, when the transistors TR11 to TR13, TR21 to TR23, TR31 to TR33, TR41 to TR43 are not distinguished, these transistors are simply referred to as the "transistors TR".

### A6.4.2 Structure of Each Transistor

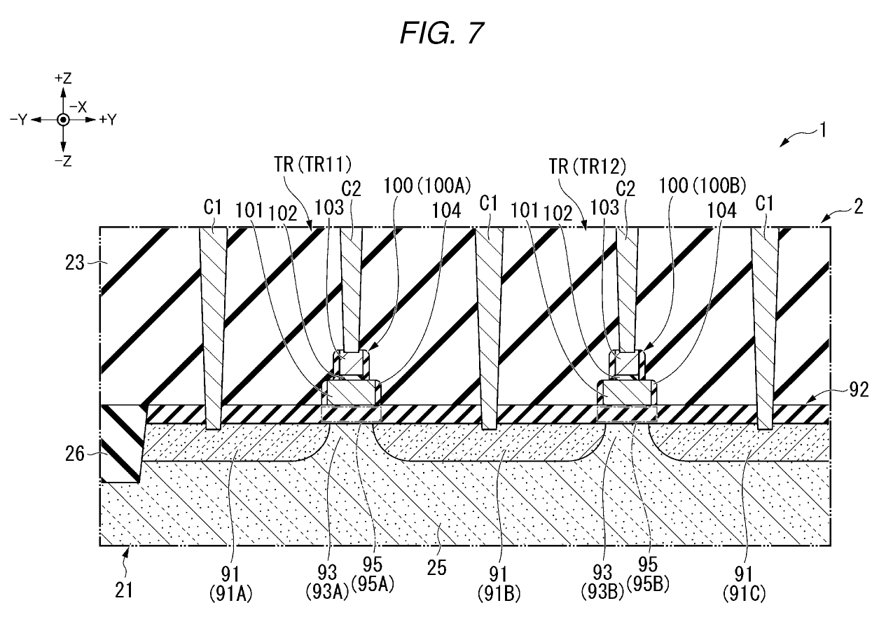

FIG. 7 is a cross-section of the structure taken along line F7-F7 in FIG. 6A. A plurality of diffusion regions 91 and an insulating film 92 are provided on the semiconductor substrate 21.

The diffusion region 91 is a region that serves as a source region or a drain region of the transistor TR. The diffusion region 91 is formed by doping impurities on the upper portion of the semiconductor substrate 21. When the element region 25 is a P-type well, the diffusion region 91 includes an N-type semiconductor. Meanwhile, when the element region 25 is an N-type well, the diffusion region 91 includes a P-type semiconductor. The plurality of diffusion regions 91 are spaced apart from each other in the Y direction. A contact C1 is connected to the diffusion region 91 from above. The contact C1 is provided between the diffusion region 91 and the wiring 22L (see FIG. 3), and electrically connects the diffusion region 91 and the wiring 22L.

The plurality of diffusion regions 91 are spaced apart from each other in the Y direction and include, for example, the diffusion region 91A, the diffusion region 91B, and a diffusion region 91C. The diffusion region 91C is positioned on the opposite side of the diffusion region 91B from the diffusion region 91A in the Y direction.

The insulating film 92 is an insulating film provided on the element region 25 and the diffusion region 91. The insulating film 92 includes, for example, a film containing silicon and oxygen (e.g., a silicon oxide film). The insulating film 92 extends along the element region 25 in the Y direction. The insulating film 92 includes a portion of the transistor TR that serves as a gate insulating film 95.

As shown in FIG. 7, each transistor TR includes, for example, two diffusion regions 91, the gate insulating film 95, and a gate electrode 100. At least a portion of the gate insulating film 95 faces a region 93 between the two diffusion regions 91 when viewed from the Z direction. The gate insulating film 95 is provided between the element region 25 and the gate electrode 100, and electrically insulates the element region 25 and the gate electrode 100.

The gate electrode 100 is positioned on the opposite side of the gate insulating film 95 from the semiconductor substrate 21. A contact C2 is connected to the gate electrode 100 from above. The contact C2 is provided between the gate electrode 100 and the wiring 22L (see FIG. 3), and electrically connects the gate electrode 100 and the wiring 22L. The gate electrode 100 will be described in detail below.

In the example shown in FIG. 7, the plurality of transistors TR includes, for example, the transistor TR11 and the transistor TR12. The transistor TR11 and the transistor TR12 are adjacent to each other in the Y direction. For example, the transistor TR11 and the transistor TR12 are adjacent to each other in the Y direction without the element isolation portion 26 in between.

For example, the transistor TR11 includes the two diffusion regions 91A and 91B, a gate insulating film 95A, and a gate electrode 100A. At least a portion of the gate insulating film 95A faces a region 93A between the two diffusion regions 91A and 91B when viewed from the Z direction. The gate electrode 100A is positioned on the opposite side of the gate insulating film 95A from the semiconductor substrate 21.

The transistor TR12 includes, for example, the two diffusion regions 91B and 91C, a gate insulating film 95B, and a gate electrode 100B. At least a portion of the gate insulating film 95B faces a region 93B between the two diffusion regions 91B and 91C when viewed from the Z direction. The gate electrode 100B is positioned on the opposite side of the gate insulating film 95B from the semiconductor substrate 21.

In the present embodiment, the two transistors TR adjacent to each other in the Y direction share the diffusion region 91 present between the two transistors TR. For example, the transistor TR11 and the transistor TR12 share the diffusion region 91B. Instead of the example described above, in some embodiments, the two transistors TR adjacent to each other in the Y direction may not share the diffusion region 91.

### A6.4.3 Structure of Gate Electrode

Next, the structure of the gate electrode 100 of the transistor TR will be described.

FIG. 8 is a cross-section of the structure taken along line F8-F8 in FIG. 6A. The gate electrode 100 includes, for example, a first conductive layer 101, the insulating layer 102, a second conductive layer 103, and an insulating film 104.

### First Conductive Layer

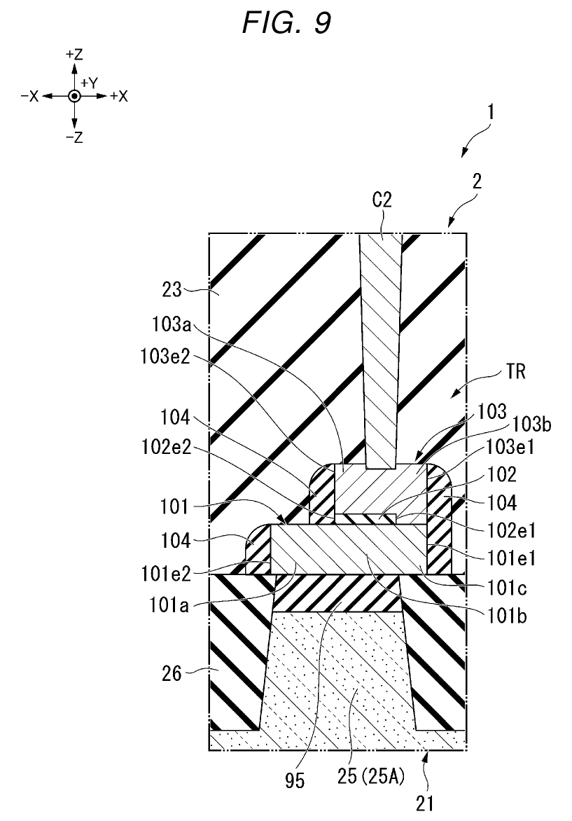

FIG. 9 is an enlarged view showing an area enclosed by line F9 shown in FIG. 8. The first conductive layer 101 is provided on the gate insulating film 95. The first conductive layer 101 is a conductive layer extending along the X direction and the Y direction. The first conductive layer 101 includes a conductive material (e.g., silicon doped with impurities). For example, the first conductive layer 101 includes the same material as the conductive layer 71 of the capacitive element 70 and the conductive layer 81 of the resistance element 80. For example, the thickness of the first conductive layer 101 in the Z direction is the same as the thickness of the conductive layer 71 of the capacitive element 70 in the Z direction and also the thickness of the conductive layer 81 of the resistance element 80 in the Z direction (see FIG. 8).

In the present embodiment, the first conductive layer 101 includes a first portion 101a, a second portion 101b, and a third portion 101c. The first portion 101a is a portion provided outside the insulating layer 102 and the second conductive layer 103 when viewed from the Z direction. The second portion 101b is a portion overlapping both the insulating layer 102 and the second conductive layer 103 when viewed from the Z direction. The third portion 101c is a portion provided outside the insulating layer 102 and overlapping the second conductive layer 103 when viewed from the Z direction.

The first conductive layer 101 includes an end 101e1 and an end 101e2 as a pair of ends in the X direction. The end 101e1 is an end of the first conductive layer 101 in the +X direction side. The end 101e2 is an end of the first conductive layer 101 in the -X direction side. The end 101e2 is positioned opposite to the end 101e1 in the X direction.

### Insulating Layer

The insulating layer 102 is positioned between the first conductive layer 101 and the second conductive layer 103 in the Z direction. The insulating layer 102 is an insulating layer extending along the X direction and the Y direction. The insulating layer 102 includes a film containing silicon and oxygen (e.g., a silicon oxide film). For example, the insulating layer 102 includes the same material as the insulating layer 72 of the capacitive element 70 and the insulating layer 82 of the resistance element 80. For example, the thickness of the insulating layer 102 in the Z direction is the same as the thickness of the insulating layer 72 of the capacitive element 70 in the Z direction and also that of the insulating layer 82 of the resistance element 80 in the Z direction (see FIG. 8).

In the present embodiment, the insulating layer 102 is provided on a surface of a portion of the first conductive layer 101 in the X direction. A length of the insulating layer 102 in the X direction is less than a length of the first conductive layer 101 in the X direction. A length of the insulating layer 102 in the X direction is less than a length of the second conductive layer 103 to be described below in the X direction.

The insulating layer 102 includes an end 102e1 and an end 102e2 as a pair of ends in the X direction. The end 102e1 is an end of the insulating layer 102 in the +X direction side. When viewed from the Z direction, the end 102e1 does not overlap with the end 101e1 of the first conductive layer 101. The end 102e1 is positioned offset from the end 101e1 of the first conductive layer 101 to the -X direction side.

Meanwhile, the end 102e2 is an end of the insulating layer 102 in the -X direction side. The end 102e2 is positioned opposite to the end 102e1 in the X direction. When viewed from the Z direction, the end 102e2 does not overlap with the end 101e2 of the first conductive layer 101. The end 102e2 is positioned offset from the end 101e2 of the first conductive layer 101 to the +X direction side.

### Second Conductive Layer

The second conductive layer 103 is provided on the insulating layer 102 and the first conductive layer 101. The second conductive layer 103 is a conductive layer extending along the X direction and the Y direction. The second conductive layer 103 includes a conductive material (e.g., silicon doped with impurities). For example, the second conductive layer 103 includes the same material as the conductive layer 73 of the capacitive element 70 and the conductive layer 83 of the resistance element 80. For example, the thickness of the second conductive layer 103 in the Z direction is the same as the thickness of the conductive layer 73 of the capacitive element 70 in the Z direction and also the thickness of the conductive layer 83 of the resistance element 80 in the Z direction (see FIG. 8).

In the present embodiment, the second conductive layer 103 includes a first portion 103a and a second portion 103b. The first portion 103a is a portion overlapping the insulating layer 102 when viewed from the Z direction. The second portion 103b is a portion provided outside the insulating layer 102 and overlapping the first conductive layer 101 when viewed from the Z direction. The second portion 103b is connected to the third portion 101c of the first conductive layer 101.

In the present embodiment, the length of the second conductive layer 103 in the X direction is less than the length of the first conductive layer 101 in the X direction. In the present embodiment, a length of the second conductive layer 103 in the Y direction is less than a length of the first conductive layer 101 in the Y direction (see FIG. 7). However, the length of the second conductive layer 103 in the Y direction may be the same as the length of the first conductive layer 101 in the Y direction.

The second conductive layer 103 includes an end 103e1 and an end 103e2 as a pair of ends in the X direction. The end 103e1 is an end of the second conductive layer 103 in the +X direction side. When viewed from the Z direction, the end 103e1 overlaps the end 101e1 of the first conductive layer 101. On the other hand, when viewed from the Z direction, the end 103e1 does not overlap with the end 102e1 of the insulating layer 102. When viewed from the Z direction, the end 103e1 is positioned offset from the end 102e1 of the insulating layer 102 to the +X direction side.

Meanwhile, the end 103e2 is an end of the second conductive layer 103 in the -X direction side. The end 103e2 is positioned opposite to the end 103e1 in the X direction. When viewed from the Z direction, the end 103e2 does not overlap with the end 101e2 of the first conductive layer 101. The end 103e2 is positioned offset from the end 101e2 of the first conductive layer 101 to the +X direction side. When viewed from the Z direction, the end 103e2 overlaps the end 102e2 of the insulating layer 102.

In the present embodiment, the contact C2 is connected to the second conductive layer 103. The contact C2 overlaps the second conductive layer 103 when viewed from the Z direction, and is connected to the second conductive layer 103 from above. In the semiconductor memory device 1, a voltage is applied to the first conductive layer 101 via the contact C2 and the second conductive layer 103.

### Insulating Film

The insulating film 104 is a protective film for preventing impurities from being injected into the gate electrode 100 when the impurities are injected to form the diffusion region 91. The insulating film 104 is provided on the side surfaces of the first conductive layer 101, the insulating layer 102, and the second conductive layer 103 in the X direction and the Y direction.

### Common Configuration of Plurality of Transistors

In the present embodiment, each gate electrode 100 of the transistors TR11 to TR13, TR21 to TR23, TR31 to TR33, TR41 to TR43 includes the first conductive layer 101, the insulating layer 102, the second conductive layer 103, and the insulating film 104 described above. In each of the transistors TR11 to TR13, TR21 to TR23, TR31 to TR33, and TR41 to TR43, the center of the second conductive layer 103 in the X direction is offset from the center of the first conductive layer 101 in the X direction to the +X direction side.

### A7. Manufacturing Method

Next, a method for manufacturing the semiconductor memory device 1 will be described.

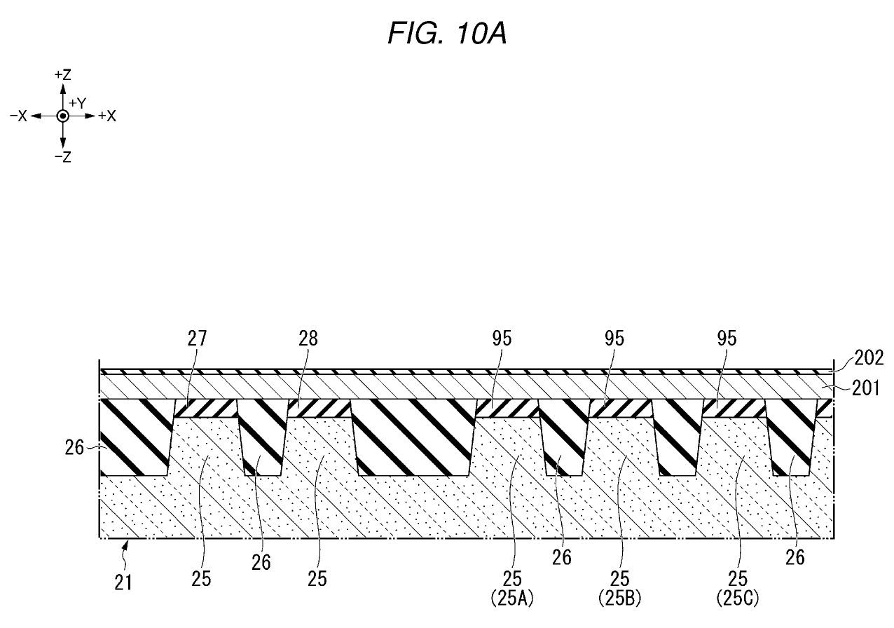

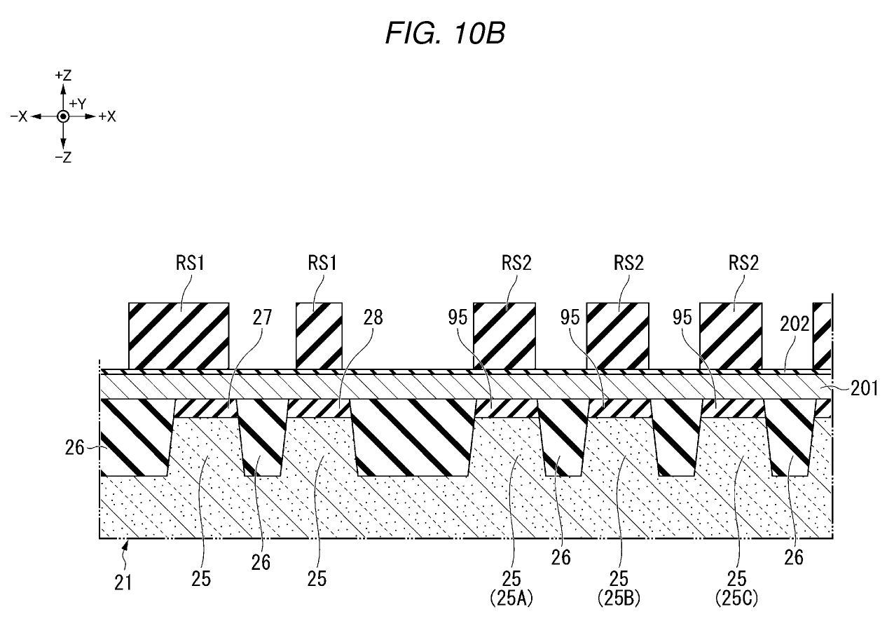

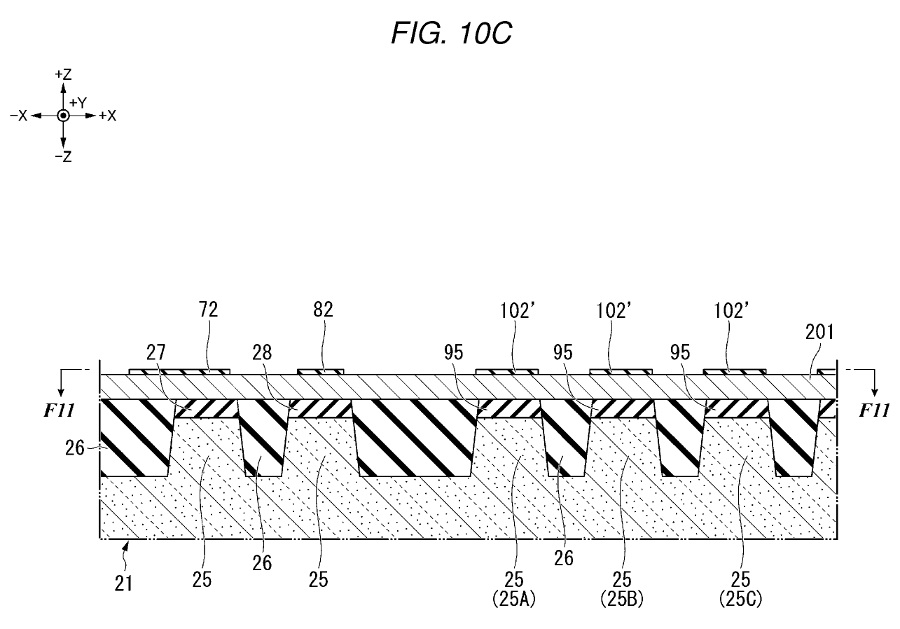

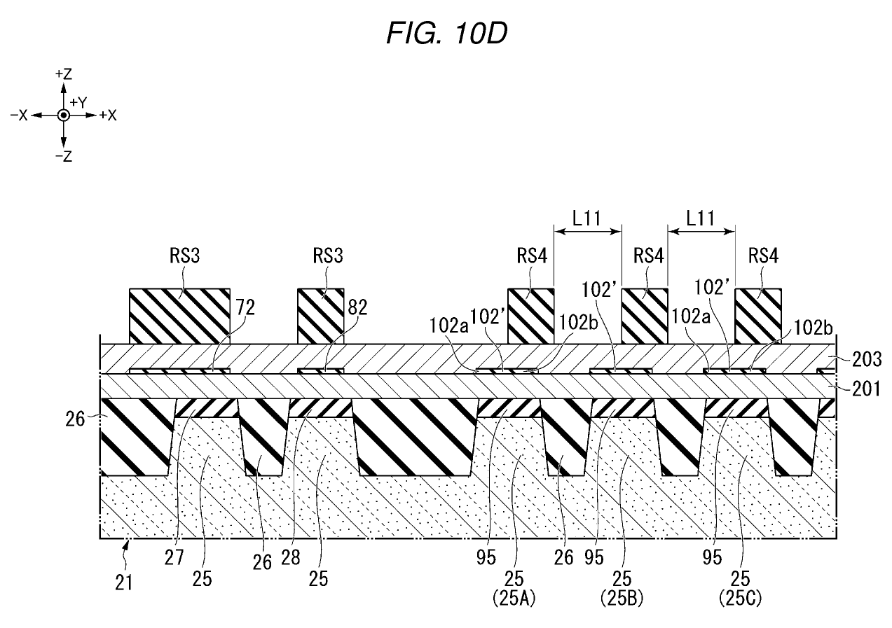

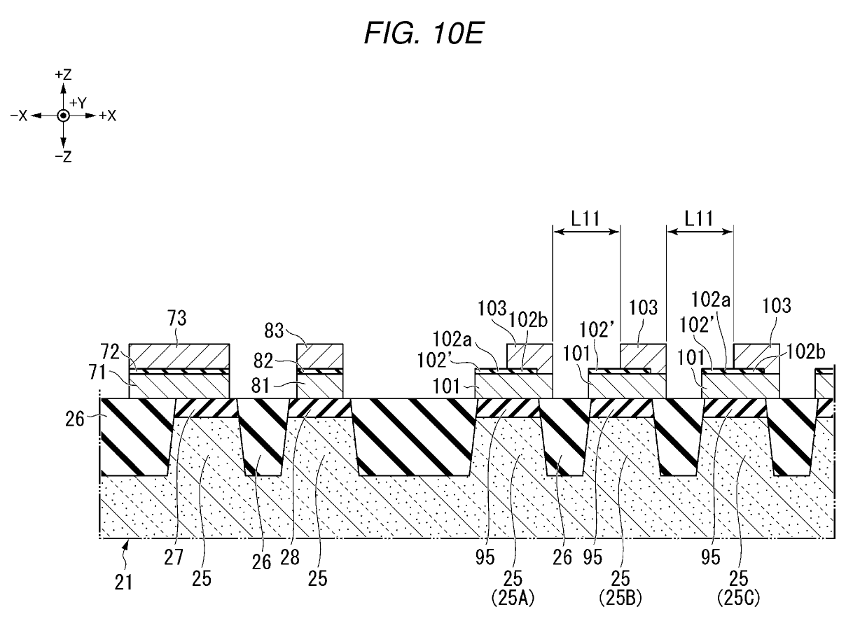

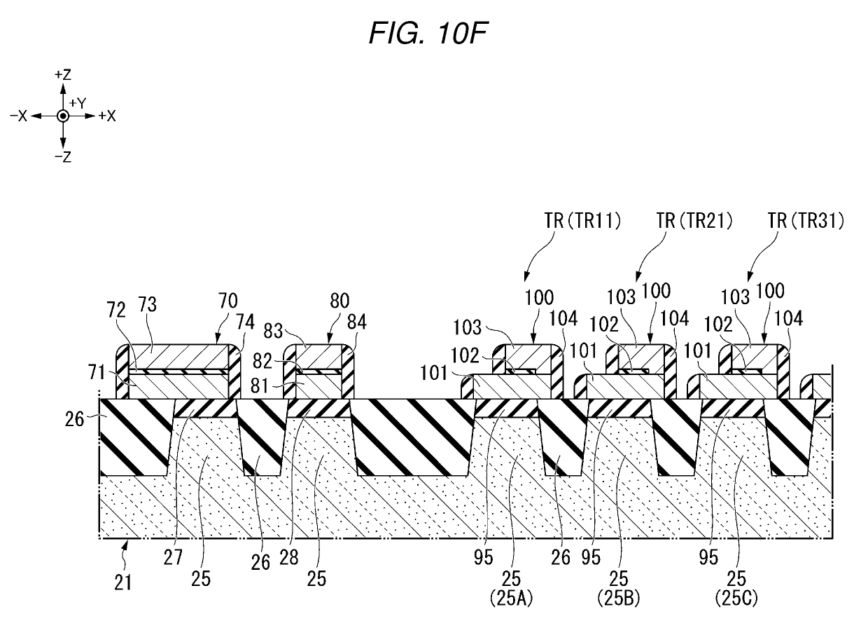

FIGS. 10A to 10F are cross-sectional views illustrating a method for manufacturing the semiconductor memory device 1. Since the second chip 3 can be manufactured by a known method, the following will describe the method for manufacturing the structure related to the peripheral circuit 22 of the first chip 2.

The element isolation portion 26, the insulating film 27 and 28 and a plurality of gate insulating films 95 are formed on the semiconductor substrate 21 by a known method, as shown in FIG. 10A. Next, a conductive material (e.g., silicon doped with impurities) is supplied onto surfaces of the element isolation portion 26, the insulating films 27 and 28, and the plurality of gate insulating films 95 to form a conductive film 201. Next, for example, a silicon material including oxygen is supplied to the conductive film 201 and oxidized to form an insulating film 202 on the conductive film 201. The conductive film 201 and the insulating film 202 extend over the element isolation portion 26, the insulating films 27 and 28, and the plurality of gate insulating films 95.

A plurality of resists RS1 and RS2 are provided on the insulating film 202 by lithography as shown in FIG. 10B. The resist RS1 is provided at a position corresponding to the insulating layer 72 of the capacitive element 70 or the insulating layer 82 of the resistance element 80 when viewed from the Z direction. On the other hand, the resist RS2 is provided at a position corresponding to an insulating layer 102' of the transistor TR to be described below when viewed from the Z direction.

As shown in FIG. 10C, etching is performed on the insulating film 202 using the resists RS1 and RS2 as the protective films, and the unnecessary portions of the insulating film 202 are removed. As a result, the insulating layer 72 of the capacitive element 70, the insulating layer 82 of the resistance element 80, and the insulating layer 102' of the transistor TR are formed from the insulating film 202.

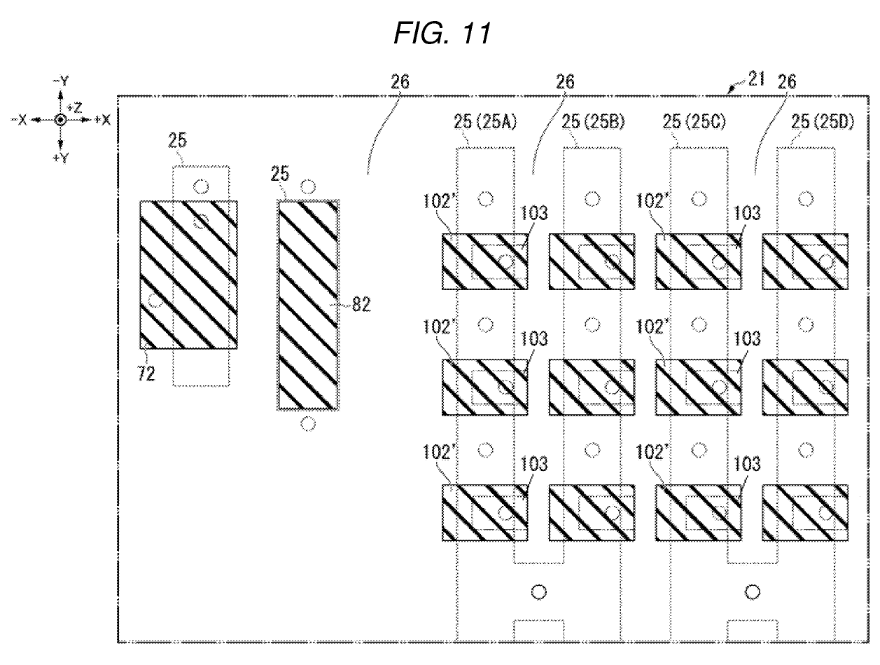

FIG. 11 is a cross-section of the structure taken along line F11-F11 in FIG. 10C. As shown in FIG. 11, at the stage when the process of FIG. 10C is completed, the insulating layer 102' is formed in a rectangular shape covering the first portion 101a (see FIG. 9) of the first conductive layer 101 of the transistor TR.

Next, as shown in FIG. 10D, a conductive material (e.g., silicon doped with impurities) is supplied on the surfaces of the conductive film 201 and the insulating layers 72, 82, and 102' to form a conductive film 203. The conductive film 203 extends over the element isolation portion 26, the insulating films 27 and 28, and the plurality of gate insulating films 95. A plurality of resists RS3 and RS4 are provided on the conductive film 203 by lithography.

The resist RS3 is provided at the same position as the insulating layer 72 of the capacitive element 70 or the insulating layer 82 of the resistance element 80 when viewed from the Z direction. On the other hand, the resist RS4 is provided at a position offset to the +X direction side with respect to the insulating layer 102' of the transistor TR when viewed from the Z direction. The resist RS4 is provided at a position corresponding to the second conductive layer 103 of the transistor TR when viewed from the Z direction. The resist RS4 covers only a portion of the insulating layer 102' when viewed from the Z direction. For example, the resist RS4 does not overlap with a first portion 102a of the insulating layer 102', but overlaps a second portion 102b of the insulating layer 102' when viewed from the Z direction. A distance L11 between the two resists RS4 adjacent to each other in the X direction is, for example, a minimum distance of a gap determined by an exposure limit. However, the dimensions of the distance L11 are not limited to the examples described above.

As shown in FIG. 10E, etching is performed on the first conductive film 201 and the second conductive film 203 using the insulating layer 102' and the resists RS3 and RS4 as the protective films, and the unnecessary portions of the first conductive film 201 and the second conductive film 203 are removed. As a result, the conductive layer 71 of the capacitive element 70, the conductive layer 81 of the resistance element 80, and the first conductive layer 101 of the transistor TR are formed from the first conductive film 201. The conductive layer 73 of the capacitive element 70, the conductive layer 83 of the resistance element 80 and the second conductive layer 103 of the transistor TR are formed from the second conductive film 203. In the present embodiment, by using the insulating layer 102' as a protective film, the first conductive layer 101 remains even in a region not covered by the resist RS4.

Next, as shown in FIG. 10F, etching is performed on the insulating layer 102' to remove the first portion 102a of the insulating layer 102' which is not covered by the second conductive layer 103. As a result, the second portion 102b of the insulating layer 102' remains as the insulating layer 102. Instead of the example described above, in alternative embodiments, the first portion 102a of the insulating layer 102' may remain in the gate electrode 100 without being removed. That is, the gate electrode 100 may include the insulating layer 102' instead of the insulating layer 102.

Next, by supplying the insulating material and forming an insulating film, the insulating film 74 of the capacitive element 70, the insulating film 84 of the resistance element 80, and the insulating film 104 of the gate electrode 100 are formed. After that, the diffusion region 91 is formed by doping impurities into a portion of the element region 25. After that, the insulating portion 23, the contacts C, C1, and C2, and the wiring part 60 are formed. As a result, the first chip 2 is formed. After that, the first chip 2 and the second chip 3, which are formed separately, are bonded together to complete the semiconductor memory device 1.

Next, a method of slimming will be described.

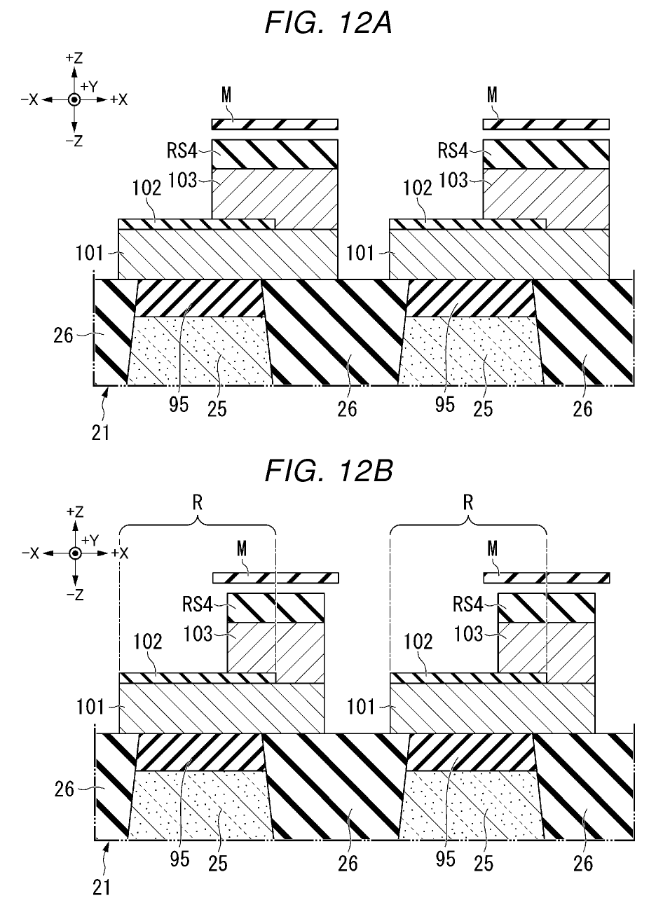

FIG. 12A is a cross-sectional view illustrating a case in which slimming is not performed. FIG. 12B is a cross-sectional view illustrating a case in which slimming is performed. The gate electrode 100 may undergo slimming so that a length of the gate electrode 100 in the Y direction (referred to as a “gate length”) can be reduced to further improve the electrical characteristics (e.g., switching speed) of the transistor TR. The slimming is performed by using a mask M provided above the resist RS4 to reduce the length of the resist RS4 in the Y direction, thereby reducing the length of the gate electrode 100 in the Y direction. FIGS. 12A and 12B are schematic diagrams for ease of description. Actual slimming is performed in the state shown in FIG. 10D (where the second conductive film 203 is present and the resist RS4 is provided on the second conductive film 203) to reduce the length of the resist RS4 in the Y direction.

In this example, when slimming is performed to reduce the length of the resist RS in the Y direction to reduce the length of the gate electrode 100 in the Y direction, the resist RS4 is etched in the X direction as shown in FIG. 12B. For this reason, the length of the gate electrode 100 in the X direction (referred to herein as a “gate width”) is unintentionally reduced. When the length of the gate electrode 100 in the X direction decreases, the magnitude of the on-current may decrease, which is not preferable.

However, in the present embodiment, the first conductive layer 101 is covered with the insulating layer 102. For this reason, when the slimming is performed for reducing the length in the Y direction (gate length), the end of the gate electrode 100 in the +X direction side is shaved off and the length of the gate electrode 100 in the X direction is reduced, but the end of the first conductive layer 101 in the -X direction side covered with the insulating layer 102 is mostly preserved. Therefore, the length of the region R in the X direction, as shown in FIG. 12B, remains substantially the same.

Accordingly, even when slimming is performed to reduce the length of the resist RS in the Y direction to reduce the length of the gate electrode 100 in the Y direction (gate length), the unintended reduction of the length of the gate electrode 100 in the X direction (gate width) is prevented compared with the structure in which the insulating layer 102 is not present. Therefore, the decrease in the magnitude of the on-current can be suppressed. It is to be noted that the slimming described above is not essential and may be omitted.

### A8. Advantages

In the semiconductor memory device, the number of transistors required for the memory capacity increase or the like has been increasing. As a result, miniaturization (e.g., reduction of area) of the semiconductor memory device is becoming increasingly difficult. For example, the distance between the gate electrodes of the plurality of transistors is regulated by the exposure limit. For this reason, it is difficult to arrange a plurality of adjacent transistors close to each other.

To miniaturize the semiconductor memory device, for example, the length of the transistor TR in the X direction (gate width) may be reduced. However, when the gate width of the transistor TR is reduced, the electrical characteristics of the semiconductor memory device, such as the magnitude of the on-current of the transistor TR, are degraded.

Meanwhile, in the present embodiment, the semiconductor memory device includes a substrate (e.g., the semiconductor substrate 21) and a first transistor (e.g., the transistor TR11). The first transistor includes a first diffusion region (e.g., the diffusion region 91A) and a second diffusion region (e.g., the diffusion region 91B) provided in the substrate, a first gate insulating film (e.g., the gate insulating film 95) having at least a portion facing a region (e.g., the region 93) between the first diffusion region and the second diffusion region, and a first gate electrode (e.g., the gate electrode 100 and 100A) positioned on the opposite side of the first gate insulating film from the substrate. The first gate electrode includes a first conductive layer (e.g., the first conductive layer 101 of the transistor TR11), a first insulating layer (e.g., the insulating layer 102 of the transistor TR11), and a second conductive layer (e.g., the second conductive layer 103 of the transistor TR11). The first insulating layer is provided on a surface of a portion of the first conductive layer. The second conductive layer includes a first portion (e.g., the first portion 103a) overlapping the first insulating layer and a second portion (e.g., the second portion 103b) overlapping the first conductive layer at a position outside the first insulating layer when viewed from the first direction (e.g., Z direction) which is the thickness direction of the substrate, and is connected to the first conductive layer.

With such a configuration, for example, the distance between the first conductive layer 101 of one transistor TR and the gate electrode 100 of the adjacent transistor TR can be reduced by using the insulating layer 102', which becomes the insulating layer 102, as the protective film. As a result, a plurality of transistors TR can be disposed at a narrow pitch. As a result, miniaturization (e.g., reduction of area) of the semiconductor memory device can be achieved.

For example, according to the configuration described above, the distance between the first conductive layer 101 of one transistor TR and the gate electrode 100 of the adjacent transistor TR can be reduced below the distance L11 which is a minimum dimension determined by the exposure limit. In this case, further miniaturization of the semiconductor memory device can be achieved.

In the present embodiment, the length of the first conductive layer in the second direction (e.g., in the X direction) intersecting the first direction is greater than the length of the second conductive layer in the second direction. With such a configuration, for example, the gate width of the transistor TR can be easily ensured. As a result, for example, the magnitude of the on-current of the transistor TR can be easily ensured. As a result, the miniaturization of the semiconductor memory device can be achieved and also the electrical characteristics of the semiconductor memory device can be improved.

In the present embodiment, the first conductive layer includes a first end (e.g., the end 101e1) positioned on the first side (e.g., +X direction side) of the second direction and a second end (e.g., the end 101e2) positioned on the second side (e.g., -X direction side) opposite to the first side in the second direction. The second conductive layer includes a third end (e.g., the end 103e1) positioned on the first side of the second direction and a fourth end (e.g., the end 103e2) positioned on the second side of the second direction. The third end overlaps the first end when viewed from the first direction. The fourth end is offset from the second end to the first side in the second direction when viewed from the first direction. With such a configuration, two transistors TR adjacent to each other in the X direction can be easily disposed at a narrower pitch. As a result, further miniaturization of the semiconductor memory device can be achieved.

In the present embodiment, the semiconductor memory device includes a second transistor (e.g., the transistor TR12). The second transistor shares the second diffusion region (e.g., the diffusion region 91B) with the first transistor, and includes a third diffusion region (e.g., the diffusion region 91C) provided in the substrate, a second gate insulating film (e.g., the gate insulating film 95) having at least a portion facing a region (e.g., the region 93) between the second diffusion region and the third diffusion region, and a second gate electrode (e.g., the gate electrodes 100 and 100B) positioned on the opposite side of the second gate insulating film from the substrate. The second transistor is positioned on the third direction (e.g., the Y direction) side intersecting the first direction and the second direction with respect to the first transistor. The second gate electrode includes a third conductive layer (e.g., the first conductive layer 101 of the transistor TR12), a second insulating layer (e.g., the insulating layer 102 of the transistor TR12), and a fourth conductive layer (e.g., the second conductive layer 103 of the transistor TR12). In the first transistor, the center of the second conductive layer in the second direction is offset from the center of the first conductive layer in the second direction to the first side in the second direction. In the second transistor, the center of the fourth conductive layer in the second direction is offset from the center of the third conductive layer in the second direction to the first side in the second direction. With such a configuration, the plurality of transistors TR may be disposed in close proximity to the different transistors TR, respectively. As a result, further miniaturization of the semiconductor memory device can be achieved.

In the present embodiment, a first contact (e.g., the contact C2) connected to the first gate electrode is provided. The first contact overlaps the second conductive layer when viewed from the first direction. With such a configuration, an allowable range for misalignment of the first contact in the X direction increases compared to when the first contact is connected to the first portion 101a of the first conductive layer 101 to be described below (see FIG. 14). As a result, the manufacturability of the semiconductor memory device can be improved.

In the present embodiment, the method for manufacturing the semiconductor memory device includes the following processes. The first insulating film (e.g., the gate insulating film 95) is formed on the substrate (e.g., the semiconductor substrate 21). The first conductive film (e.g., the first conductive film 201) is formed on the first insulating film. The second insulating film (e.g., the insulating film 202) is formed on the first conductive film. The first resist (e.g., the resist RS2) is formed to cover a portion of the second insulating film, and etching is performed to remove unnecessary portions of the second insulating film, thereby forming the insulating layer (e.g., the insulating layer 102'). The second conductive film (e.g., the second conductive film 203) is formed on the insulating layer and the first conductive film. The second resist (e.g., the resist RS4) is formed on the second conductive film when viewed from the thickness direction (e.g., the Z direction) of the substrate so as not to overlap with the first portion (e.g., the first portion 102a) of the insulating layer, but to overlap with the second portion (e.g., the second portion 102b) of the insulating layer. Etching is performed using the insulating layer and the second resist as the protective films, and the gate electrode (e.g., the gate electrode 100) is formed, which includes the first conductive layer (e.g., the first conductive layer 101) obtained from the first conductive film, the second conductive layer (e.g., the second conductive layer 103) obtained from the second conductive film, and at least a portion of the insulating layer (e.g., the insulating layer 102).

With such a configuration, for example, the distance between the first conductive layer 101 of one transistor TR and the gate electrode 100 of the adjacent transistor TR can be reduced by using the insulating layer 102', which becomes the insulating layer 102, as the protective film. As a result, the plurality of transistors TR can be disposed at a narrow pitch. As a result, miniaturization (e.g., reduction of area) of the semiconductor memory device can be achieved.

In the present embodiment, the insulating layer 102 of the transistor TR is formed by utilizing a part of a process of forming the insulating layer 72 of the capacitive element 70 or the insulating layer 82 of the resistance element 80. In this case, a special process of providing the insulating layer 102 of the transistor TR is not required. As a result, the manufacturability of the semiconductor memory device can be improved.

### A9. Modifications

Next, certain modifications according to the first embodiment will be described. It is to be noted that, except for the configurations described below in each modification, the other configurations are the same as those according to the first embodiment described above.

### A9.1 First Modification

FIG. 13 is a cross-sectional view showing a part of a semiconductor memory device 1A according to a first modification. FIG. 14 is a cross-section of the structure taken along line F14-F14 in FIG. 13. In the first embodiment described above, the contact C2 is disposed at a position overlapping the second conductive layer 103 of the gate electrode 100 when viewed from the Z direction, and is connected to the second conductive layer 103 of the gate electrode 100.

In the first modification, the contact C2 is disposed at a position outside the second conductive layer 103 of the gate electrode 100 and overlapping the first portion 101a of the first conductive layer 101 when viewed from the Z direction. The contact C2 is connected to the first portion 101a of the first conductive layer 101 from above. The contact C2 is directly connected to the first conductive layer 101.

With such a configuration, as in the first embodiment described above, miniaturization (e.g., reduction of area) of the semiconductor memory device can be achieved. Further, according to the configuration of the first modification, when the first portion 101a of the first conductive layer 101 can be formed greater than that of the second conductive layer 103, the allowable range for the misalignment of the contact C2 increases. As a result, the manufacturability of the semiconductor memory device can be improved.

### A9.2 Second Modification

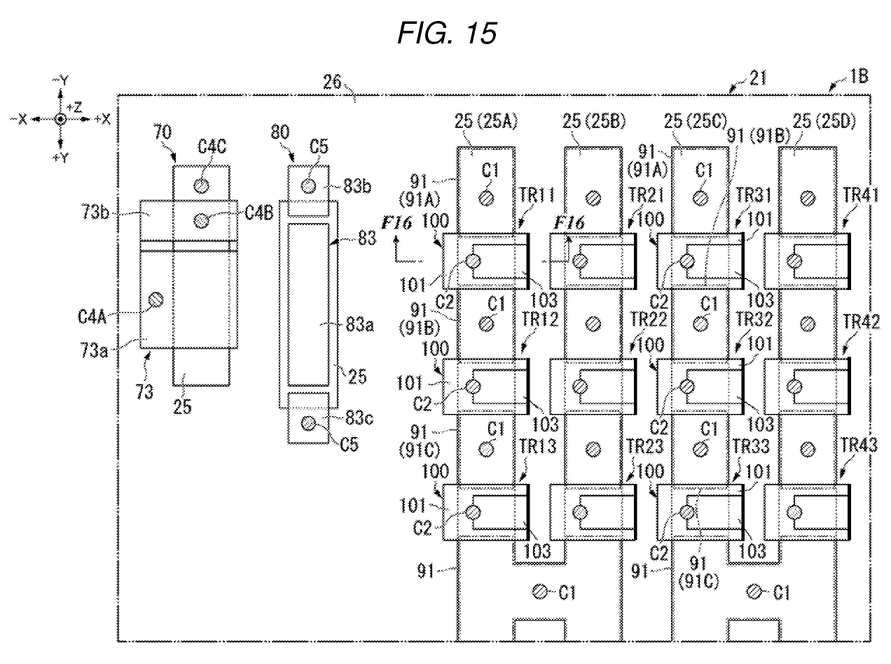

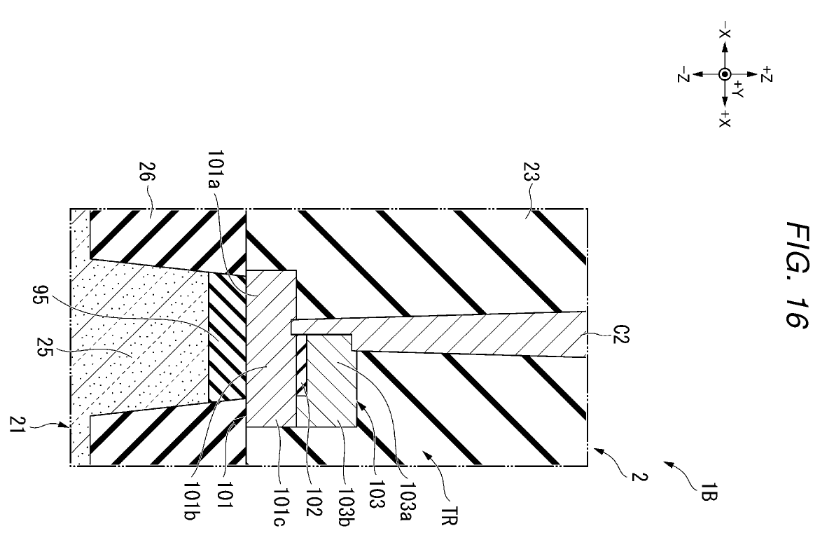

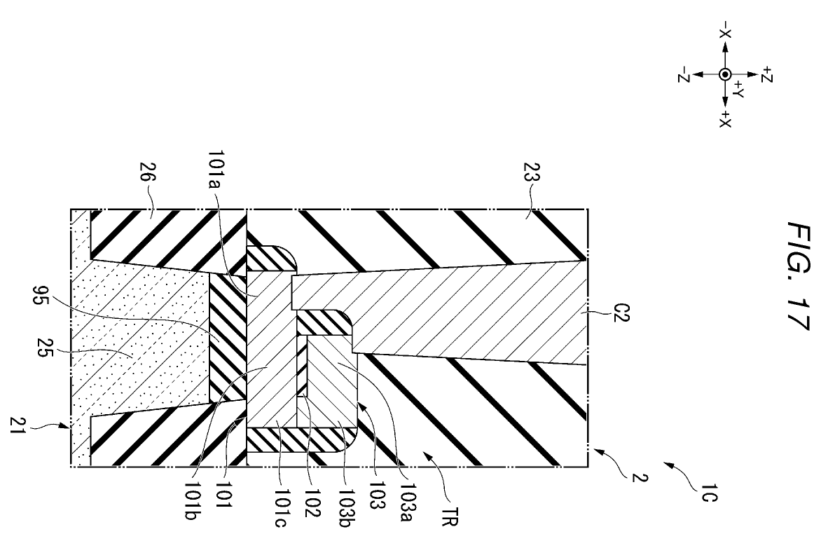

FIG. 15 is a cross-sectional view showing a part of a semiconductor memory device 1B according to a second modification. FIG. 16 is a cross-section of the structure taken along a line F16-F16 in FIG. 15. In the second modification, the contact C2 is disposed at a position overlapping both the first portion 101a of the first conductive layer 101 and the second conductive layer 103 of the gate electrode 100 when viewed from the Z direction. In the second modification, after the process of doping impurities to form the diffusion region 91 is performed, the process of removing the insulating film 104 is performed, so that the insulating film 104 is not present. The contact C2 is connected to the first portion 101a of the first conductive layer 101 and the second conductive layer 103 of the gate electrode 100 from above. The contact C2 is directly connected to the first portion 101a of the first conductive layer 101 and the second conductive layer 103 of the gate electrode 100, respectively.

With such a configuration, as in the first embodiment described above, miniaturization (e.g., reduction of area) of the semiconductor memory device can be achieved. Further, according to the configuration of the second modification, the allowable range for misalignment of the contact C2 increases. As a result, the manufacturability of the semiconductor memory device can be improved.

### A9.3 Third Modification

FIG. 17 is a cross-sectional view showing a part of a semiconductor memory device 1C according to a third modification. In the third modification, the contact C2 is disposed at a position overlapping both the first portion 101a of the first conductive layer 101 and the second conductive layer 103 of the gate electrode 100 when viewed from the Z direction. In the third modification, the insulating film 104 is present. The contact C2 is connected from above to the first portion 101a, the second conductive layer 103, and the insulating film 104 of the first conductive layer 101 of the gate electrode 100. The contact C2 is directly connected to the first portion 101a of the first conductive layer 101 and the second conductive layer 103 of the gate electrode 100, respectively.

With such a configuration, as in the first embodiment described above, miniaturization (e.g., reduction of area) of the semiconductor memory device can be achieved. Further, according to the configuration of the third modification, the allowable range for the misalignment of the contact C2 increases. As a result, the manufacturability of the semiconductor memory device can be improved.

### A9.4 Fourth Modification

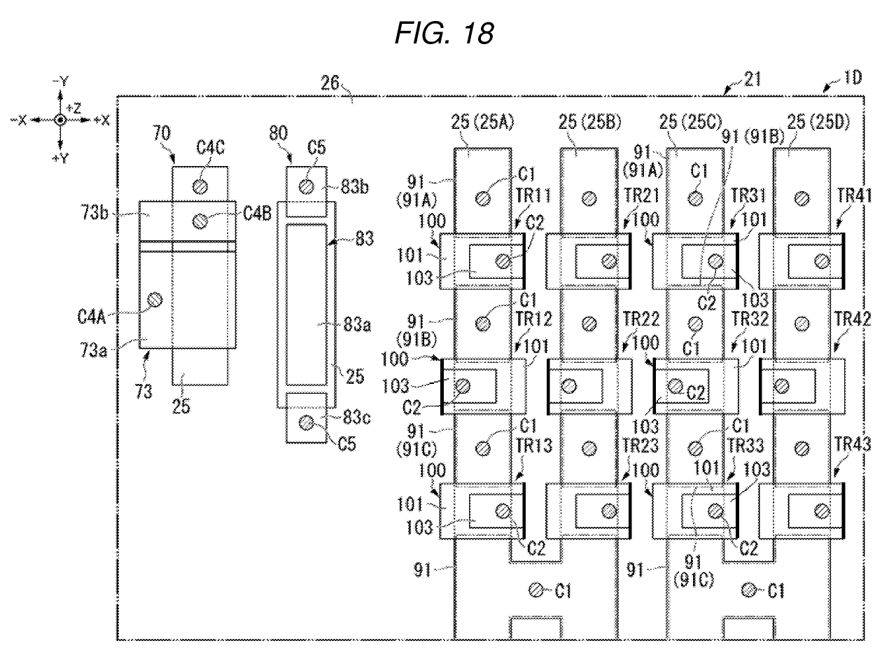

FIG. 18 is a cross-sectional view showing a part of a semiconductor memory device 1D according to a fourth modification. In the first embodiment described above, in the gate electrode 100 of all transistors TR, the center of the second conductive layer 103 in the X direction is offset from the center of the first conductive layer 101 in the X direction to the +X direction side. Meanwhile, in the fourth modification, in the gate electrode 100 of some transistors TR, the center of the second conductive layer 103 in the X direction is offset from the center of the first conductive layer 101 in the X direction to the -X direction side.

For example, in each gate electrode 100 of the transistors TR11, TR21, TR31, and TR41, the center of the second conductive layer 103 in the X direction is offset from the center of the first conductive layer 101 in the X direction to the +X direction side. Likewise, in each gate electrode 100 of the transistors TR13, TR23, TR33, and TR43, the center of the second conductive layer 103 in the X direction is offset from the center of the first conductive layer 101 in the X direction to the +X direction side.

Meanwhile, in the gate electrodes 100 of the transistors TR12, TR22, TR32, and TR42, the center of the second conductive layer 103 in the X direction is offset from the center of the first conductive layer 101 in the X direction to the -X direction side.

As described above, in the present embodiment, the semiconductor memory device includes the second transistor (e.g., the transistor TR12). The second transistor shares the second diffusion region (e.g., the diffusion region 91B) with the first transistor (e.g., the transistor TR11), and includes the third diffusion region (e.g., the diffusion region 91C) provided in the substrate, the second gate insulating film (e.g., the gate insulating film 95) having at least a portion facing a region (e.g., the region 93) between the second diffusion region and the third diffusion region, and a second gate electrode (e.g., the gate electrodes 100 and 100B) positioned on the opposite side of the second gate insulating film from the substrate. The second transistor is positioned on the third direction (e.g., the Y direction) side intersecting the first direction and the second direction with respect to the first transistor. The second gate electrode includes the third conductive layer (e.g., the first conductive layer 101 of the transistor TR12), the second insulating layer (e.g., the insulating layer 102 of the transistor TR12), and the fourth conductive layer (e.g., the second conductive layer 103 of the transistor TR12). In the first transistor, the center of the second conductive layer in the second direction (e.g., in the X direction) is offset from the center of the first conductive layer in the second direction to the first side in the second direction. In the second transistor, the center of the fourth conductive layer in the second direction is offset from the center of the third conductive layer in the second direction to a second side opposite to the first side in the second direction.

With such a configuration, since the position of the second conductive layer in the X direction are different between the first transistor and the second transistor, when the insulating portion 23 (FIG. 8) is provided to cover the first transistor and the second transistor, a step in the Z direction is less likely to occur in the insulating portion 23. As a result, the manufacturability of the semiconductor memory device can be improved.

### Second Embodiment

Next, a second embodiment will be described. The second embodiment differs from the first embodiment in that an electrode 130 is provided in the diffusion region 91. It is to be noted that, except for the configurations described below, the other configurations are the same as those according to the first embodiment described above.

### B1. Second Chip Configuration

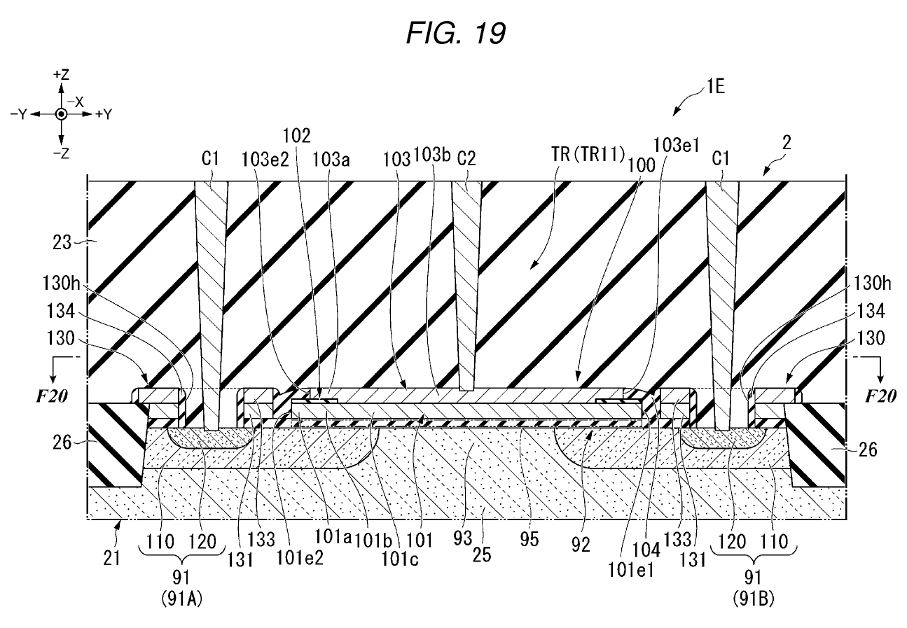

FIG. 19 is a cross-sectional view showing a part of a semiconductor memory device 1E according to the second embodiment. In the present embodiment, the Z direction is an example of a "first direction". The Y direction is an example of a "second direction". The plurality of diffusion regions 91 and the insulating film 92 are provided on the semiconductor substrate 21.

### Diffusion Region

The plurality of diffusion regions 91 include, for example, the diffusion region 91A and the diffusion region 91B as the two diffusion regions 91 spaced apart in the Y direction. One of the diffusion region 91A and the diffusion region 91B serves as a source region of the transistor TR. The other of the diffusion region 91A and the diffusion region 91B serves as a drain region of the transistor TR. Hereinafter, when the diffusion region 91A and the diffusion region 91B are not distinguished, they are simply referred to as "the diffusion region 91". For example, the diffusion region 91 includes a low-concentration diffusion region 110 (high-resistance diffusion layer) and a high-concentration diffusion region 120 (low-resistance diffusion layer).

The low-concentration diffusion region 110 is formed by doping impurities on the upper portion of the semiconductor substrate 21. The low-concentration diffusion region 110 includes impurities at a first impurity concentration. The low-concentration diffusion region 110 includes, for example, an N⁻-type semiconductor. The low-concentration diffusion region 110 is provided across a region overlapping the contact C1 and a region overlapping a portion of the gate electrode 100 when viewed from the Z direction.

The high-concentration diffusion region 120 is formed by additionally doping a portion of the low-concentration diffusion region 110 with impurities. The high-concentration diffusion region 120 includes impurities at a second impurity concentration higher than the first impurity concentration. The high-concentration diffusion region 120 includes, for example, an N⁺-type semiconductor. The high-concentration diffusion region 120 is provided across a region outside the gate electrode 100 and overlapping the contact C1 when viewed from the Z direction. In the present embodiment, the contact C1 is connected to the high-concentration diffusion region 120.

### Insulating Film

The insulating film 92 is an insulating film provided on the element region 25 and the diffusion region 91. The insulating film 92 includes a portion of the transistor TR that serves as the gate insulating film 95. The gate insulating film 95 includes a portion facing the region 93 between the two diffusion regions 91A and 91B corresponding to the transistor TR when viewed from the Z direction.

### B2. Configuration of Transistor

As shown in FIG. 19, each transistor TR includes, for example, the two diffusion regions 91A and 91B, the gate insulating film 95, the gate electrode 100, and the electrode 130 for electric field shielding described below. In this example, the structure of the electrode 130 will be described first, and then the structure of the gate electrode 100 will be described.

### Electrode for Electric Field Shielding

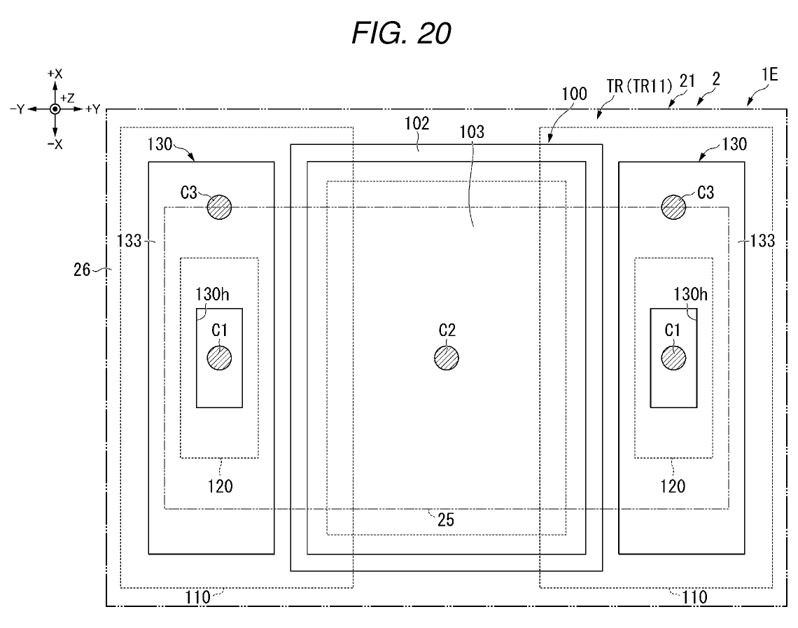

The electrode 130 is provided on the diffusion region 91. When viewed from the Z direction, the electrode 130 is formed in a C-shape or annular shape surrounding at least a portion of the entire periphery of the contact C1. The electrode 130 includes an opening 130hthrough which the contact C1 is passed. The opening 130h is formed through the electrode 130 in the Z direction. In the present description, the term "surrounding at least a portion of the entire periphery" is not limited to surrounding in an annular closed state, but may also include a case in which a partially open C-shaped electrode 130 faces from a plurality of directions (e.g., three directions). In the present embodiment, the electrode 130 is formed in an annular shape surrounding the entire periphery of the contact C1 (see FIG. 20).

In the present embodiment, the wiring 22L or the wiring part 60 is provided above the transistor TR. When the wiring 22L or the wiring part 60 is present, the resistance of the diffusion region 91 (e.g., the resistance of the low-concentration diffusion region 110) may vary due to the potential effect of the wiring 22L or the wiring part 60, which may affect the characteristics of the transistor TR. The electrode 130 is, for example, an electrode provided to prevent the potential effect as described above. A contact C3 is connected to the electrode 130 (see FIG. 20). The electrode 130 is applied with a predetermined voltage through the contact C3 to shield at least a part of the potential effect on the diffusion region 91.

The electrode 130 includes, for example, a conductive layer 131, a conductive layer 133, and an insulating film 134. The conductive layer 131 and the conductive layer 133 are stacked on the diffusion region 91 in this order (i.e., in the order of the conductive layer 131 and the conductive layer 133). The contact C3 (see FIG. 20) is connected to the conductive layer 133. The contact C3 is provided between the electrode 130 and the wiring 22L (see FIG. 3), and electrically connects the electrode 130 and the wiring 22L. The insulating film 134 is provided on side surfaces of the conductive layer 131 and the conductive layer 133 in the X direction and the Y direction.

Each of the conductive layer 131 and the conductive layer 133 includes a conductive material (e.g., silicon doped with impurities). The insulating film 134 includes, for example, a film containing silicon and oxygen (e.g., a silicon oxide film).

### Gate Electrode

Next, the gate electrode 100 will be described. The gate electrode 100 includes, for example, the first conductive layer 101, the insulating layer 102, the second conductive layer 103, and the insulating film 104.

### First Conductive Layer

The first conductive layer 101 is provided on the gate insulating film 95. The first conductive layer 101 is a conductive layer extending along the X direction and the Y direction. The first conductive layer 101 includes a conductive material (e.g., silicon doped with impurities). For example, the first conductive layer 101 includes the same material as the conductive layer 131 of the electrode 130. For example, a thickness of the first conductive layer 101 in the Z direction is the same as a thickness of the conductive layer 131 of the electrode 130 in the Z direction.

The first conductive layer 101 includes the end 101e1 and the end 101e2 as a pair of ends in the Y direction. The end 101e1 is an end of the first conductive layer 101 in the +Y direction side. The end 101e2 is an end of the first conductive layer 101 in the -Y direction side. The end 101e2 is positioned opposite to the end 101e1 in the Y direction.

### Insulating Layer

The insulating layer 102 is positioned between the first conductive layer 101 and the second conductive layer 103. The insulating layer 102 is an insulating layer extending along the X direction and the Y direction. The insulating layer 102 is provided on a surface of a portion of the first conductive layer 101 in the Y direction. A length of the insulating layer 102 in the Y direction is less than a length of the first conductive layer 101 in the Y direction. The length of the insulating layer 102 in the Y direction is less than a length of the second conductive layer 103 to be described below in the Y direction.

FIG. 20 is a cross-section of the structure taken along line F20-F20 in FIG. 19. The insulating layer 102 is formed in a rectangular frame shape along an outer periphery of the gate electrode 100 when viewed from the Z direction.

### Second Conductive Layer

Returning to FIG. 19, the second conductive layer 103 will be described. The second conductive layer 103 is provided on the insulating layer 102 and the first conductive layer 101. The second conductive layer 103 is a conductive layer extending along the X direction and the Y direction. The second conductive layer 103 includes a conductive material (e.g., silicon doped with impurities). For example, the second conductive layer 103 is formed of the same material as the conductive layer 133 of the electrode 130. For example, a thickness of the second conductive layer 103 in the Z direction is the same as a thickness of the conductive layer 133 of the electrode 130 in the Z direction.

The second conductive layer 103 includes the end 103e1 and the end 103e2 as a pair of ends in the Y direction. The end 103e1 is an end of the second conductive layer 103 in the +Y direction side. When viewed from the Z direction, the end 103e1 does not overlap with the end 101e1 of the first conductive layer 101. When viewed from the Z direction, the end 103e1 is positioned on the -Y direction side from the end 101e1 of the first conductive layer 101.

The end 103e2 is an end of the second conductive layer 103 in the -Y direction side. The end 103e2 is positioned opposite to the end 103e1 in the Y direction. When viewed from the Z direction, the end 103e2 does not overlap with the end 101e2 of the first conductive layer 101. When viewed from the Z direction, the end 103e2 is positioned offset from the end 101e2 of the first conductive layer 101 in the +Y direction side.

In the present embodiment, the length of the second conductive layer 103 in the Y direction is less than the length of the first conductive layer 101 in the Y direction (see FIG. 20). However, the length of the second conductive layer 103 in the Y direction may be the same as the length of the first conductive layer 101 in the Y direction. This content will be described in the first modification to be described below.

### B3. Manufacturing Method

Next, a method for manufacturing the semiconductor memory device 1E will be described.

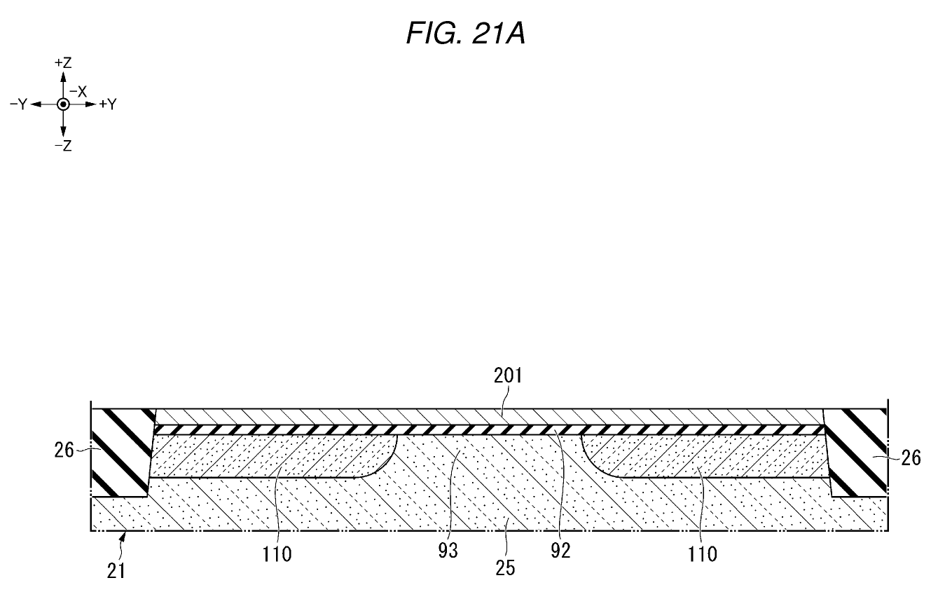

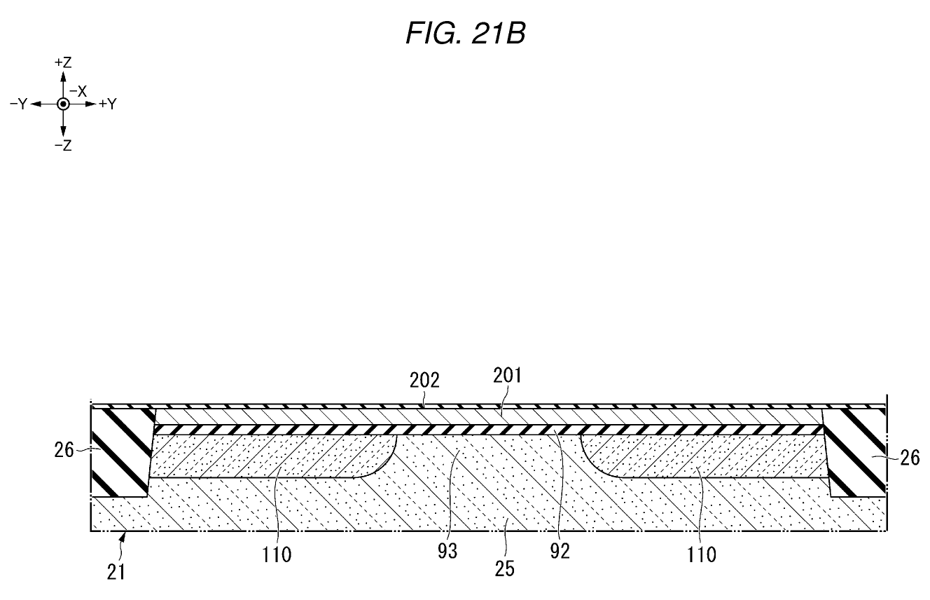

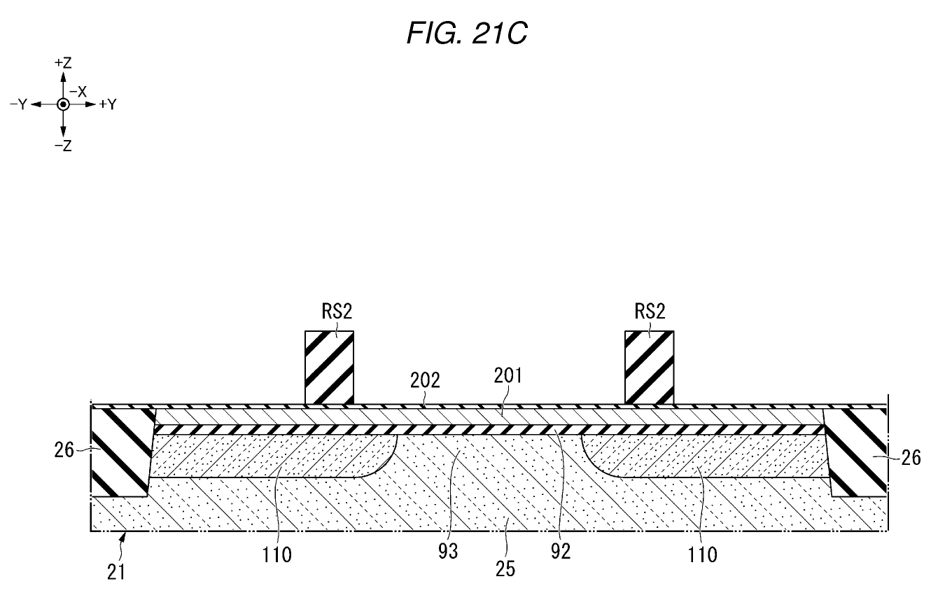

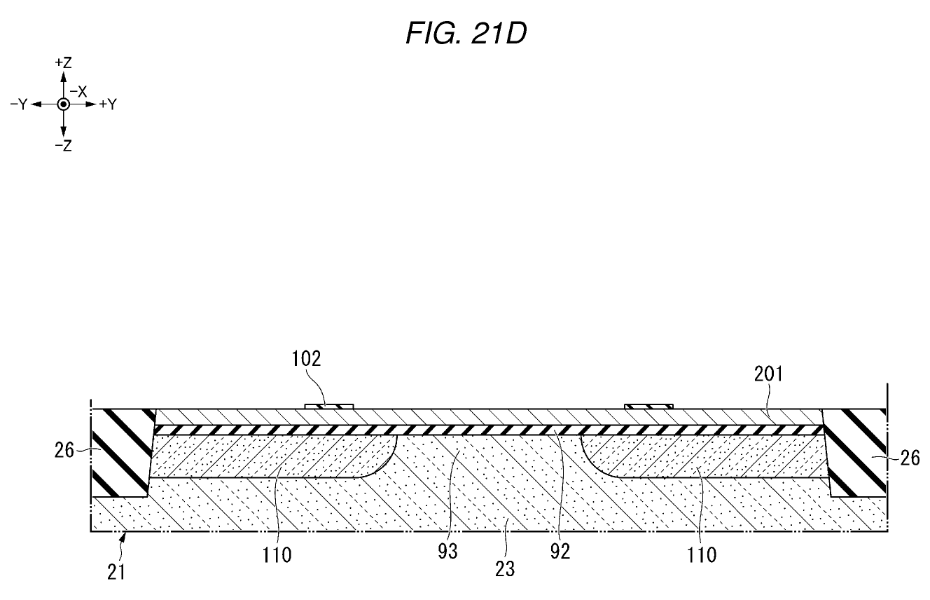

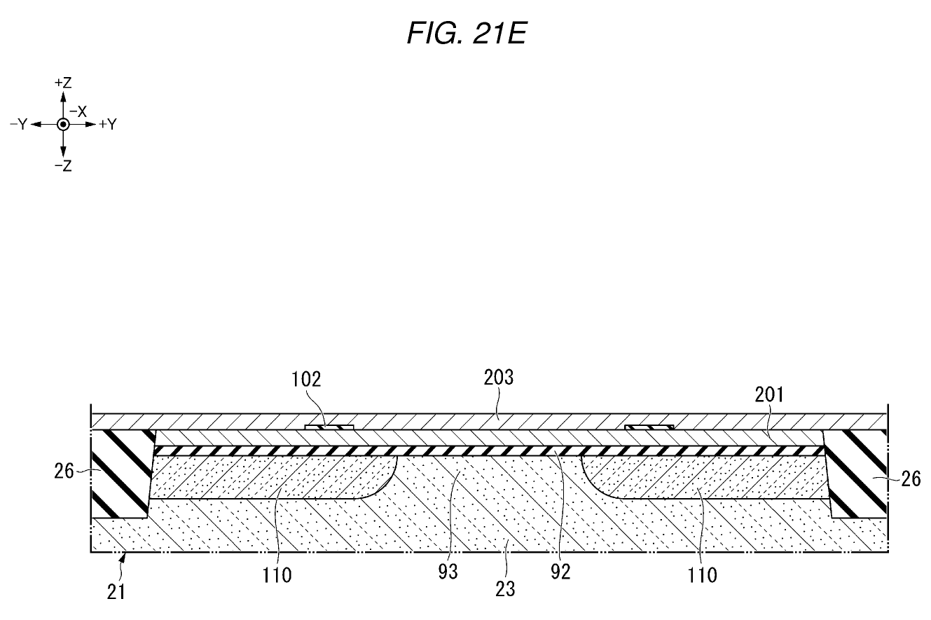

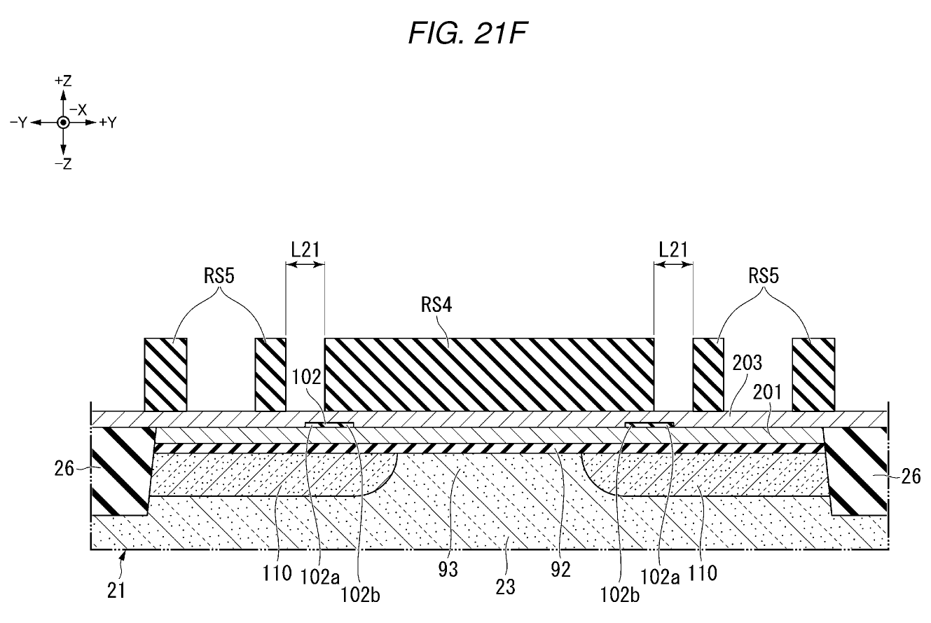

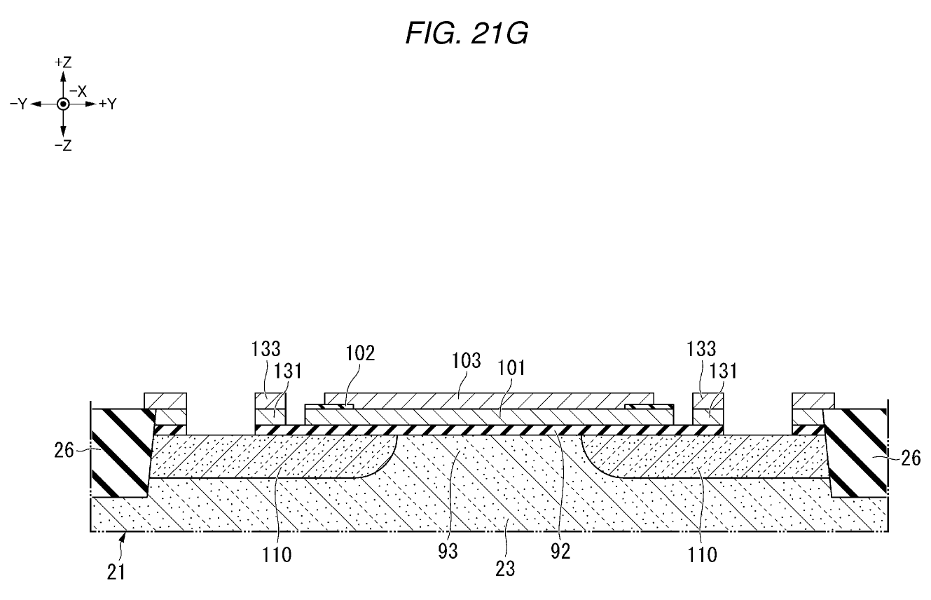

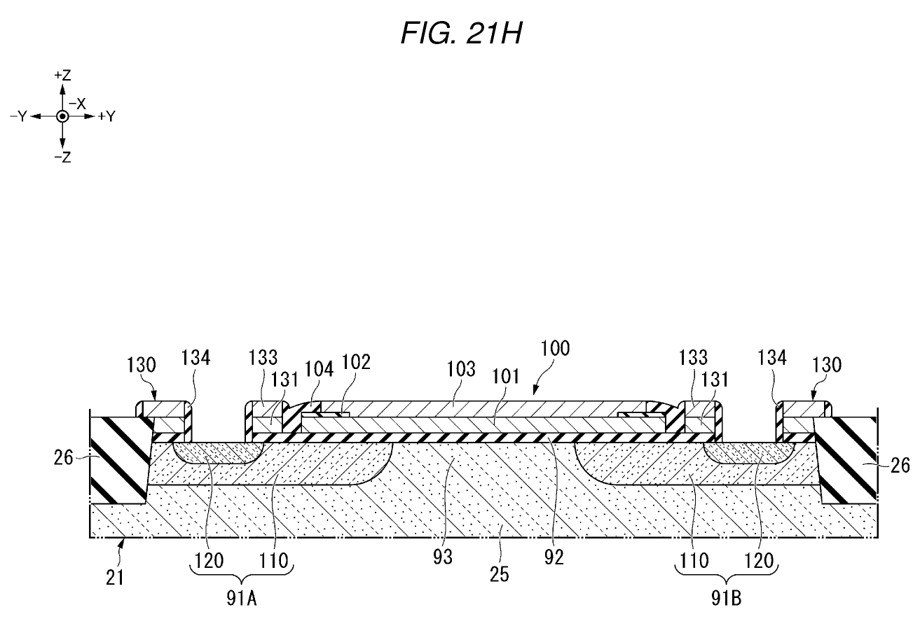

FIGS. 21A to 21H are cross-sectional views illustrating the method for manufacturing the semiconductor memory device 1E. Since the second chip 3 can be manufactured by a known method, the following will describe the method for manufacturing the structure related to the peripheral circuit 22 of the first chip 2. Although not shown in the second embodiment, the insulating layer 102 of the transistor TR of the second embodiment may be formed by a part of the process of forming at least one of the insulating layer 72 of the capacitive element 70 and the insulating layer 82 of the resistance element 80 as in the first embodiment.

First, as shown in FIG. 21A, the element isolation portion 26, the low-concentration diffusion region 110, and the insulating film 92 are formed on the semiconductor substrate 21 by a known method. A conductive material (e.g., silicon doped with impurities) is supplied above the surfaces of the element isolation portion 26, the low-concentration diffusion region 110, and the insulating film 92 to form the conductive film 201. The conductive film 201 extends along the insulating film 92 above the two low-concentration diffusion regions 110 and the region 93 between the two low-concentration diffusion regions 110.

Next, as shown in FIG. 21B, for example, a silicon material is supplied onto the surface of the conductive film 201 and oxidized to form the insulating film 202. The insulating film 202 extends over the element isolation portion 26, the two low-concentration diffusion regions 110, and the region 93 between the two low-concentration diffusion regions 110.

A plurality of resists RS2 are provided on the insulating film 202 by lithography as shown in FIG. 21C. The resist RS2 is provided at a position corresponding to the insulating layer 102 of the transistor TR when viewed from the Z direction.

Next, as shown in FIG. 21D, etching is performed using the resist RS2 as the protective film, and the unnecessary portions of the insulating film 202 are removed. As a result, the insulating layer 102 of the transistor TR is formed from the insulating film 202.

Next, as shown in FIG. 21E, a conductive material (e.g., silicon doped with impurities) is supplied onto the surfaces of the conductive layer 201 and the insulating layer 102, so that the conductive film 203 is formed.

A plurality of resists RS4 and RS5 are provided on the conductive film 203 by lithography as shown in FIG. 21F. When viewed from the Z direction, the resist RS4 is provided at a position corresponding to the second conductive layer 103 of the gate electrode 100. The resist RS4 is provided at a position offset in the Y direction with respect to the insulating layer 102 when viewed from the Z direction. When viewed from the Z direction, the resist RS4 does not overlap with the first portion 102a of the insulating layer 102, but overlaps the second portion 102b of the insulating layer 102.

Meanwhile, the resist RS5 is provided at a position corresponding to the conductive layers 131 and 133 of the electrode 130. A distance L21 between the resist RS4 and the resist RS5 is, for example, a minimum distance determined by the exposure limit. However, the dimensions of the distance L21 are not limited to the examples described above.

Next, as shown in FIG. 21G, etching is performed using the insulating layer 102 and the resists RS4 and RS5 as the protective films, and the unnecessary portions of the first conductive film 201 and the second conductive film 203 are removed. As a result, the first conductive layer 101 of the gate electrode 100 and the conductive layer 131 of the electrode 130 are formed from the first conductive film 201. The second conductive layer 103 of the gate electrode 100 and the conductive layer 133 of the electrode 130 are formed from the second conductive film 203. As in the first embodiment, the first portion 102a of the insulating layer 102 may be removed by another etching process.

Next, as shown in FIG. 21H, the insulating material is supplied to form the insulating film 104 of the gate electrode 100 and the insulating film 134 of the electrode 130. Furthermore, impurities are additionally doped to form the high-concentration diffusion region 120. After that, the insulating portion 23 and the contacts C2 and C3 are formed. After that, the wiring part 60 is formed. As a result, the first chip 2 is formed. After that, the first chip 2 and the second chip 3, which are formed separately, are bonded together to complete the semiconductor memory device 1E.

### B4. Advantages

When the electrode 130 described above is provided, electric field concentration may occur at a separation point between the electrode 130 and the gate electrode 100, resulting in a decrease in the breakdown voltage of the transistor. Although enlarging a region where the low-concentration diffusion region 110 and the gate electrode 100 overlap with each other in the Z direction is effective in alleviating the electric field concentration, the distance between the electrode 130 and the gate electrode 100 is limited by the exposure limit. For this reason, it is difficult to dispose the electrode 130 and the gate electrode 100 close to each other. This makes it difficult to reduce the size (e.g., reduce the area) of the semiconductor memory device.

Meanwhile, in the present embodiment, the gate electrode of the transistor includes the first conductive layer (e.g., the first conductive layer 101), the insulating layer (e.g., the insulating layer 102) and the second conductive layer (e.g., the second conductive layer 103). The insulating layer is provided on the surface of a portion of the first conductive layer. The second conductive layer includes the first portion (e.g., the first portion 103a) overlapping the insulating layer and the second portion (e.g., the second portion 103b) overlapping the first conductive layer at a position outside the insulating layer when viewed from the first direction (e.g., Z direction) which is the thickness direction of the substrate, and is connected to the first conductive layer.

With such a configuration, the distance between the gate electrode of the transistor and the electrode for electric field shielding (e.g., the electrode 130) can be reduced by using the insulating layer 102 as the protective film. As a result, miniaturization (e.g., reduction of area) of the semiconductor memory device can be achieved.

For example, with the configuration described above, the distance between the gate electrode 100 of the transistor TR and the electrode 130 for electric field shielding can be reduced below the distance L21, which is a minimum dimension determined by the exposure limit. In this case, further miniaturization of the semiconductor memory device can be achieved.

In the present embodiment, the length of the first conductive layer in the second direction (e.g., in the X direction) intersecting the first direction is greater than the length of the second conductive layer in the second direction. The second direction (e.g., the X direction) is a direction from the first diffusion region toward the second diffusion region. With such a configuration, it is easy to enlarge the region where the low-concentration diffusion region 110 and the gate electrode 100 overlap in the Z direction. As a result, the miniaturization of the semiconductor memory device can be achieved and also the electrical characteristics of the semiconductor memory device can be improved.

In the present embodiment, the first conductive layer includes the first end (e.g., the end 101e1) positioned on the first side (e.g., +Y direction side) of the second direction and the second end (e.g., the end 101e2) positioned on the second side (e.g., -Y direction side) opposite to the first side in the second direction. The second conductive layer includes the third end (e.g., the end 103e1) positioned on the first side of the second direction and the fourth end (e.g., the end 103e2) positioned on the second side of the second direction. The third end is offset from the first end to the second side in the second direction when viewed from the first direction. The fourth end is offset from the second end to the first side in the second direction when viewed from the first direction. With such a configuration, when the electrodes 130 are disposed on both sides of the gate electrode 100, the distance between the electrodes 130 on both sides and the gate electrode 100 can be reduced. As a result, further miniaturization of the semiconductor memory device can be achieved.

### B5. Modifications

Next, certain modifications according to the second embodiment will be described. It is to be noted that, except for the configurations described below in each modification, the other configurations are the same as those according to the second embodiment described above.

### B5.1 First Modification

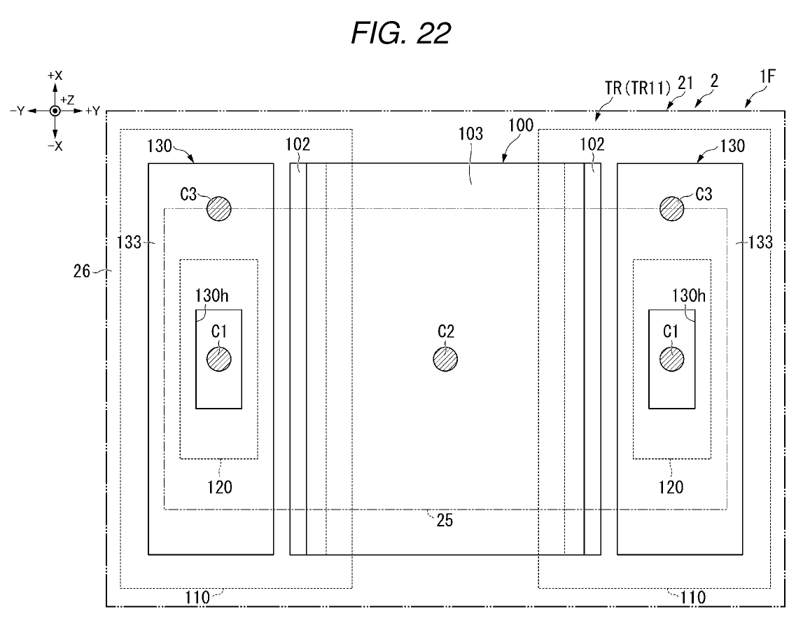

FIG. 22 is a cross-sectional view showing a part of a semiconductor memory device 1F according to a first modification. In the second embodiment described above, the insulating layer 102 of the gate electrode 100 is formed in a rectangular annular shape along the outer periphery of the gate electrode 100 when viewed from the Z direction. Meanwhile, in the first modification, the insulating layer 102 of the gate electrode 100 is provided at both end portions (i.e., end portions in the +Y direction side and end portions in the -Y direction side) of the gate electrode 100 in the Y direction when viewed from the Z direction. The insulating layer 102 is not provided at the end of the gate electrode 100 in the X direction.

With this configuration, it is possible to reduce the size of the semiconductor memory device as in the second embodiment.

### B5.2 Second Modification

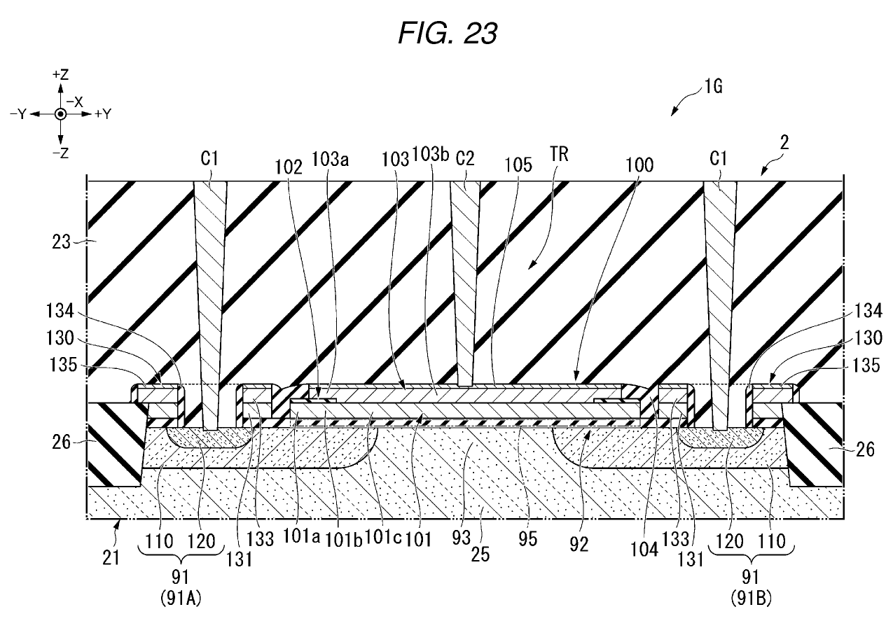

FIG. 23 is a cross-sectional view showing a part of a semiconductor memory device 1G according to a second modification. In the second modification, the gate electrode 100 includes a third conductive layer 105 in addition to the first conductive layer 101, the insulating layer 102, and the second conductive layer 103. The third conductive layer 105 is, for example, formed on the second conductive layer 103.

Further, the electrode 130 for electric field shielding includes a conductive layer 135 in addition to the conductive layer 131, an insulating layer 132, and the conductive layer 133. The conductive layer 135 is formed on the conductive layer 133. The conductive layer 135 includes the same material as the third conductive layer 105 of the gate electrode 100.

As an example, the first conductive layer 101 and the conductive layer 131 include polysilicon doped with impurities. The insulating layer 102 and the insulating layer 132 include a film containing silicon and oxygen (e.g., a silicon oxide film). The second conductive layer 103 and the conductive layer 133 include polysilicon. The third conductive layer 105 and the conductive layer 135 include metal silicide (e.g., NiPtSi).

It is noted that materials of each layer of the gate electrode 100 and the electrode 130 are not limited to the examples described above. For example, instead of the examples described above, a stacked structure including tungsten (W), titanium nitride (TiN), titanium (Ti), silicon oxide film (SiO₂), and polysilicon may also be used.

Certain embodiments and modifications have been described above. However, the embodiments and modifications are not limited to the examples described above. For example, the embodiments and modifications described above may be implemented in combination with each other. For example, the gate electrode 100 according to the first embodiment may include the third conductive layer 105 as in the second modification of the second embodiment. The "conductive layer" as used herein may refer not only to a layer formed by a single conductive material, but also to a structure formed by stacking a plurality of layers each including different conductive materials.

The embodiments and modifications described above may be applied to semiconductor devices other than semiconductor memory devices. Examples of the semiconductor device other than the semiconductor memory device include a semiconductor component (e.g., a semiconductor integrated circuit) such as a Central Processing Unit (CPU), a Graphics Processing Unit (GPU), an Application Specific Integrated Circuit (ASIC), a Programmable Logic Device (PLD), or a Field Programmable Gate Array (FPGA).

According to at least one of the embodiments described above, the semiconductor memory device includes the substrate and the first transistor. The first transistor includes the first diffusion region and the second diffusion region provided in the substrate, the first gate insulating film having at least a portion facing a region between the first diffusion region and the second diffusion region, and the first gate electrode positioned on the opposite side of the first gate insulating film from the substrate. The first gate electrode includes the first conductive layer, the first insulating layer, and the second conductive layer. The first insulating layer is provided on the surface of a portion of the first conductive layer. The second conductive layer includes, when viewed from a first direction which is a thickness direction of the substrate, the first portion overlapping the first insulating layer and the second portion disposed at a position not overlapping the first insulating layer and overlapping the first conductive layer, and is electrically connected to the first conductive layer. With such a configuration, miniaturization of the semiconductor memory device can be achieved.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device, comprising:
a substrate; and
a first transistor including a first diffusion region and a second diffusion region provided in the substrate, a first gate insulating film having at least a portion facing a region between the first diffusion region and the second diffusion region, and a first gate electrode positioned on the opposite side of the first gate insulating film from the substrate, wherein
the first gate electrode includes:
a first conductive layer;
a first insulating layer provided on a surface of a portion of the first conductive layer; and
a second conductive layer that includes, when viewed from a first direction which is a thickness direction of the substrate, a first portion overlapping the first insulating layer and a second portion disposed at a position not overlapping the first insulating layer and overlapping the first conductive layer, and that is electrically connected to the first conductive layer.

2. The semiconductor memory device according to claim 1, wherein a length of the first conductive layer in a second direction intersecting the first direction is greater than a length of the second conductive layer in the second direction.

3. The semiconductor memory device according to claim 2, wherein
each of the first and second conductive layers includes a first end positioned on a first side thereof in the second direction and a second end positioned on a second side thereof opposite to the first side thereof in the second direction,
the first end of the second conductive layer overlaps the first end of the first conductive layer when viewed from the first direction, and
the second end of the second conductive layer is offset from the second end of the first conductive layer toward the first sides of the first and second conductive layers in the second direction when viewed from the first direction.

4. The semiconductor memory device according to claim 2, further comprising a second transistor that shares the second diffusion region with the first transistor and also includes a third diffusion region provided on the substrate, a second gate insulating film having at least a portion facing a region between the second diffusion region and the third diffusion region, and a second gate electrode positioned on the opposite side of the second gate insulating film from the substrate, wherein
the second transistor is aligned with the first transistor along a third direction intersecting the first direction and the second direction,
the second gate electrode includes a third conductive layer, a second insulating layer, and a fourth conductive layer,
in the first transistor, a center of the second conductive layer in the second direction is offset from a center of the first conductive layer in the second direction to one side thereof in the second direction, and
in the second transistor, a center of the fourth conductive layer in the second direction is offset from a center of the third conductive layer in the second direction to one side thereof in the second direction.

5. The semiconductor memory device according to claim 4, wherein directions of the offset of the center of the second conductive layer and the offset of the center of the fourth conductive layer are the same.

6. The semiconductor memory device according to claim 4, wherein directions of the offset of the center of the second conductive layer and the offset of the center of the fourth conductive layer are opposite.

7. The semiconductor memory device according to claim 2, further comprising a first contact connected to the first gate electrode, wherein
the first conductive layer includes a first portion offset from the second conductive layer when viewed from the first direction, and
the first contact overlaps the first portion of the first conductive layer and the second conductive layer when viewed from the first direction, and is electrically connected to the first portion of the first conductive layer and to the second conductive layer.

8. The semiconductor memory device according to claim 2, further comprising a first contact connected to the first gate electrode, wherein
the first conductive layer includes a first portion offset from the second conductive layer when viewed from the first direction, and
the first contact overlaps the first portion of the first conductive layer when viewed from the first direction and is electrically connected to the first portion of the first conductive layer.

9. The semiconductor memory device according to claim 2, further comprising a first contact connected to the first gate electrode, wherein
the first contact overlaps the second conductive layer when viewed from the first direction and is electrically connected to the second conductive layer.

10. The semiconductor memory device according to claim 2, wherein
the first conductive layer includes a first end positioned on a first side thereof in the second direction and a second end positioned on a second side thereof opposite to the first side thereof in the second direction,
the second conductive layer includes a third end positioned on a first side thereof in the second direction and a fourth end positioned on a second side thereof opposite to the first side thereof in the second direction,
the third end is offset from the first end to the second side of the second conductive layer in the second direction when viewed from the first direction, and
the fourth end is offset from the second end to the first side of the second conductive layer in the second direction when viewed from the first direction.

11. The semiconductor memory device according to claim 2, further comprising:
a first contact connected to the first gate electrode;
a second contact connected to the first diffusion region;
a first electrode overlapping the first diffusion region and also surrounding at least a portion of an entire periphery of the second contact when viewed from the first direction; and
a third contact connected to the first electrode, wherein
the first gate electrode is adjacent to the first electrode in the second direction.

12. The semiconductor memory device according to claim 11, wherein the first electrode surrounds the entire periphery of the second contact when viewed from the first direction.

13. The semiconductor memory device according to claim 2, wherein a length of the first conductive layer in a third direction intersecting the first and second directions is the same as a length of the second conductive layer in the third direction.

14. A method for manufacturing a semiconductor memory device, the method comprising:
forming a first insulating film on a substrate;
forming a first conductive film on the first insulating film;
forming a second insulating film on the first conductive film;
forming an insulating layer by forming a first resist to cover a first portion of the second insulating film and performing etching to remove a second portion of the second insulating film;
forming a second conductive film on the insulating layer and on the first conductive film;
forming a second resist on the second conductive film so as not to overlap a first portion of the insulating layer, but to overlap a second portion of the insulating layer when viewed from a first direction, which is a thickness direction of the substrate, and
forming a gate electrode including a first conductive layer obtained from the first conductive film, a second conductive layer obtained from the second conductive film, and at least a portion of the insulating layer, by performing etching using the insulating layer and the second resist as protective films.

15. The method according to claim 14, wherein a length of the first conductive layer in a second direction intersecting the first direction is greater than a length of the second conductive layer in the second direction.

16. The method according to claim 15, wherein
each of the first and second conductive layers includes a first end positioned on a first side thereof in the second direction and a second end positioned on a second side thereof opposite to the first side thereof in the second direction,
the first end of the second conductive layer overlaps the first end of the first conductive layer when viewed from the first direction, and
the second end of the second conductive layer is offset from the second end of the first conductive layer toward the first sides of the first and second conductive layers in the second direction when viewed from the first direction.

17. The method according to claim 15, further comprising:
forming a first contact connected to the first gate electrode, wherein
the first conductive layer includes a portion offset from the second conductive layer when viewed from the first direction, and
the first contact overlaps the portion of the first conductive layer and the second conductive layer when viewed from the first direction, and is electrically connected to the portion of the first conductive layer and to the second conductive layer.

18. The method according to claim 15, further comprising:
forming a first contact connected to the first gate electrode, wherein
the first conductive layer includes a portion offset from the second conductive layer when viewed from the first direction, and
the first contact overlaps the portion of the first conductive layer when viewed from the first direction and is electrically connected to the portion of the first conductive layer.

19. The method according to claim 15, further comprising:
forming a first contact connected to the first gate electrode, wherein
the first contact overlaps the second conductive layer when viewed from the first direction and is electrically connected to the second conductive layer.

20. The method according to claim 15, wherein a length of the first conductive layer in a third direction intersecting the first and second directions is the same as a length of the second conductive layer in the third direction.
